(19) United States
(12) Patent Application Publication
(10) Pub. No.: US 2026/0082561 A1
(43) Pub. Date: Mar. 19, 2026

(54) SEMICONDUCTOR MEMORY DEVICE

(71) Applicant: Kioxia Corporation, Tokyo (JP)

(72) Inventors: Natsuki FUKUDA, Yokkaichi Mie (JP); Tadashi IGUCHI, Yokkaichi Mie (JP)

(21) Appl. No.: 19/070,431

(22) Filed: Mar. 4, 2025

(30) Foreign Application Priority Data
Sep. 18, 2024 (JP) 2024-160650

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

A semiconductor memory device includes a plurality of conductive layers arranged in a first direction and extending along a second direction crossing the first direction, a semiconductor column penetrating the conductive layers, a charge storage film between the semiconductor column and the conductive layers, a conductive line extending above the conductive layers in the first direction and electrically connected to the semiconductor column, and a contact electrode penetrating one or more of the conductive layers to contact an upper surface of one of the conductive layers other than said one or more of the conductive layers. The semiconductor column includes a plurality of first portions arranged in the first direction, and a width in the second direction of an upper part of each of the first portions is greater than a width in the second direction of a lower part of said each of the first portions.

### CROSS-REFERENCE TO RELATED APPLICATION

This application is based upon and claims the benefit of priority from Japanese Patent Application No. 2024-160650, filed Sep. 18, 2024, the entire contents of which are incorporated herein by reference.

### FIELD

Embodiments described herein relate generally to a semiconductor memory device.

### BACKGROUND

A semiconductor memory device including a plurality of conductive layers stacked in a stacking direction, a semiconductor column extending through the plurality of conductive layers, and a charge storage film provided between the conductive layers and the semiconductor column is known. For example, the charge storage film is an insulating charge storage film such as silicon nitride (Si₃N₄) or a conductive charge storage film such as a floating gate. The charge storage film is a part of a memory cell capable of storing data.

### BREIF DESCRIPTION OF THE DRAWINGS

FIG. 1 is a schematic plan view of a memory die according to an embodiment.

FIG. 2 is a schematic enlarged view of a portion indicated by A and a portion indicated by B in FIG. 1.

FIG. 3 is a schematic enlarged view of a portion indicated by C in FIG. 2.

FIG. 4 is a schematic cross-sectional view when a structure shown in FIG. 3 is taken along line D-D′ and viewed in a direction of an arrow.

FIG. 5 is a schematic enlarged view of a portion indicated by E in FIG. 4.

FIG. 6 is a schematic cross-sectional view when a structure shown in FIG. 2 is taken along line F-F′ and viewed in a direction of an arrow.

FIG. 7 is a schematic cross-sectional view when the structure shown in FIG. 2 is taken along line G-G′ and viewed in a direction of an arrow.

FIG. 8 is a schematic cross-sectional view showing an enlarged portion in FIG. 6.

FIG. 9 is a schematic cross-sectional view illustrating a manufacturing method of a semiconductor memory device according to an embodiment.

FIG. 10 is a schematic cross-sectional view illustrating the manufacturing method.

FIG. 11 is a schematic plan view illustrating the manufacturing method.

FIG. 12 is a schematic cross-sectional view illustrating the manufacturing method.

FIG. 13 is a schematic cross-sectional view illustrating the manufacturing method.

FIG. 14 is a schematic cross-sectional view illustrating the manufacturing method.

FIG. 15 is a schematic cross-sectional view illustrating the manufacturing method.

FIG. 16 is a schematic plan view illustrating the manufacturing method.

FIG. 17 is a schematic cross-sectional view illustrating the manufacturing method.

FIG. 18 is a schematic cross-sectional view illustrating the manufacturing method.

FIG. 19 is a schematic cross-sectional view illustrating the manufacturing method.

FIG. 20 is a schematic cross-sectional view illustrating the manufacturing method.

FIG. 21 is a schematic cross-sectional view illustrating the manufacturing method.

FIG. 22 is a schematic cross-sectional view illustrating the manufacturing method.

FIG. 23 is a schematic cross-sectional view illustrating the manufacturing method.

FIG. 24 is a schematic plan view illustrating the manufacturing method.

FIG. 25 is a schematic cross-sectional view illustrating the manufacturing method.

FIG. 26 is a schematic cross-sectional view illustrating the manufacturing method.

FIG. 27 is a schematic cross-sectional view illustrating the manufacturing method.

FIG. 28 is a schematic cross-sectional view illustrating the manufacturing method.

FIG. 29 is a schematic plan view illustrating the manufacturing method.

FIG. 30 is a schematic cross-sectional view illustrating the manufacturing method.

FIG. 31 is a schematic cross-sectional view illustrating the manufacturing method.

FIG. 32 is a schematic cross-sectional view illustrating the manufacturing method.

FIG. 33 is a schematic cross-sectional view illustrating the manufacturing method.

FIG. 34 is a schematic cross-sectional view illustrating the manufacturing method.

FIG. 35 is a schematic cross-sectional view illustrating the manufacturing method.

FIG. 36 is a schematic cross-sectional view illustrating the manufacturing method.

FIG. 37 is a schematic plan view illustrating the manufacturing method.

FIG. 38 is a schematic cross-sectional view illustrating the manufacturing method.

FIG. 39 is a schematic cross-sectional view illustrating the manufacturing method.

FIG. 40 is a schematic cross-sectional view illustrating the manufacturing method.

FIG. 41 is a schematic cross-sectional view illustrating the manufacturing method.

FIG. 42 is a schematic plan view of a semiconductor memory device according to a comparative example.

FIG. 43 is a schematic cross-sectional view when a structure shown in FIG. 42 is taken along line H-H′ and viewed in a direction of an arrow.

FIG. 44 is a schematic cross-sectional view when the structure shown in FIG. 42 is taken along line I-I′ and viewed in a direction of an arrow.

FIG. 45 is a schematic cross-sectional view illustrating a manufacturing method of a semiconductor memory device according to a comparative example.

FIG. 46 is a schematic cross-sectional view illustrating a manufacturing method of a semiconductor memory device according to a comparative example.

FIG. 47 is a schematic cross-sectional view of a semiconductor memory device according to another embodiment.

### DETAILED DESCRIPTION

Embodiments provide a semiconductor memory device that is easily highly integrated.

In general, according to one embodiment, a semiconductor memory device comprises a plurality of conductive layers arranged in a first direction and extending along a second direction crossing the first direction; a semiconductor column penetrating the conductive layers; a charge storage film between the semiconductor column and the conductive layers; a conductive line extending above the conductive layers in the first direction and electrically connected to the semiconductor column; and a contact electrode penetrating one or more of the conductive layers to contact an upper surface of one of the conductive layers other than said one or more of the conductive layers. The semiconductor column includes a plurality of first portions arranged in the first direction, wherein a width in the second direction of an upper part of each of the first portions is greater than a width in the second direction of a lower part of said each of the first portions. The contact electrode includes a plurality of second portions arranged in the first direction, wherein a width in the second direction of an upper part of each of the second portions is greater than a width in the second direction of a lower part of said each of the second portions. A total number of the second portions is greater than a total number of the first portions.

Next, embodiments of this disclosure will be described in detail with reference to the drawings. The embodiments described below are merely examples, and are not intended to limit the present disclosure. For convenience of description, some configurations and the like may be omitted. In addition, the same reference numerals will be assigned to common elements in a plurality of embodiments, and description thereof may be omitted.

The term “semiconductor memory device” used in the present specification may mean a memory die, or may mean a memory system including a controller die such as a memory chip, a memory card, and a solid state drive (SSD). Additionally, the term “semiconductor memory device” may mean an apparatus including a host computer such as a smartphone, a tablet terminal, and a personal computer.

In the present specification, when it is described that a first element is “electrically connected” to a second element, the first element may be directly connected to the second element, or the first element may be connected to the second element via a wire, a semiconductor member, a transistor, or the like. For example, when three transistors are connected in series, a first transistor is “electrically connected” to a third transistor even in a state where a second transistor is turned off.

In the present specification, when it is described that a first element is “connected between” a second element and a third element, the description may mean when the first element, the second element, and the third element are connected in series, and the second element is connected to the third element via the first element.

In the present specification, a predetermined direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

In the present specification, a direction intersecting a front surface of the substrate may be referred to as a stacking direction. A direction along a predetermined surface intersecting the stacking direction may be referred to as a first direction, and a direction intersecting the first direction along the predetermined surface may be referred to as a second direction. The stacking direction may coincide with or does not need to coincide with the Z-direction. In addition, a first direction and a second direction may correspond to or do not need to correspond to any of the X-direction and the Y-direction.

In the present specification, expressions such as “up” and “down” are based on the substrate. For example, a direction away from the substrate along the Z-direction will be referred to as up, and a direction closer to the substrate along the Z-direction will be referred to as down. When a lower surface or a lower end of a certain configuration is referred to, the description indicates a surface or an end portion on a side of the substrate of the configuration, and when an upper surface or an upper end is referred to, the description indicates a surface or an end portion on a side opposite to the substrate of the configuration. A surface intersecting the X-direction or the Y-direction will be referred to as a side surface or the like.

In the present specification, when a “width”, a “length”, a “thickness”, or the like in a predetermined direction for a configuration, a member, or the like is referred to, the description may mean a width, a length, a thickness, or the like in a cross section or the like observed by scanning electron microscopy (SEM), transmission electron microscopy (TEM), and the like.

### Embodiments

### Configuration

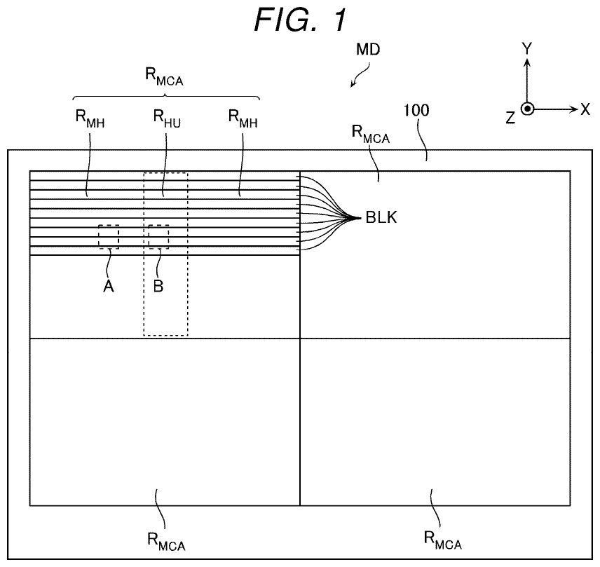

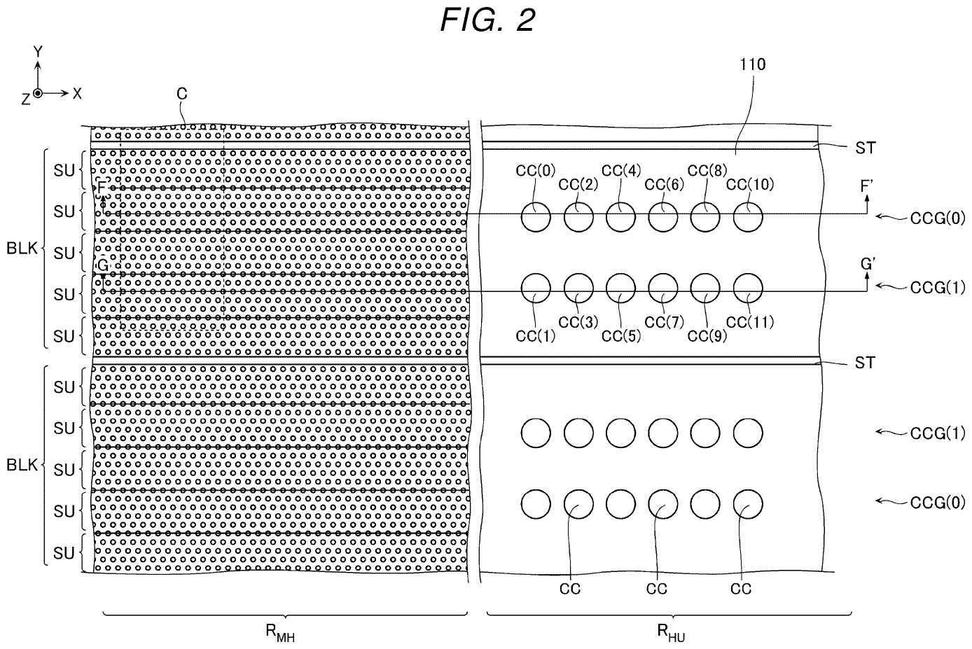

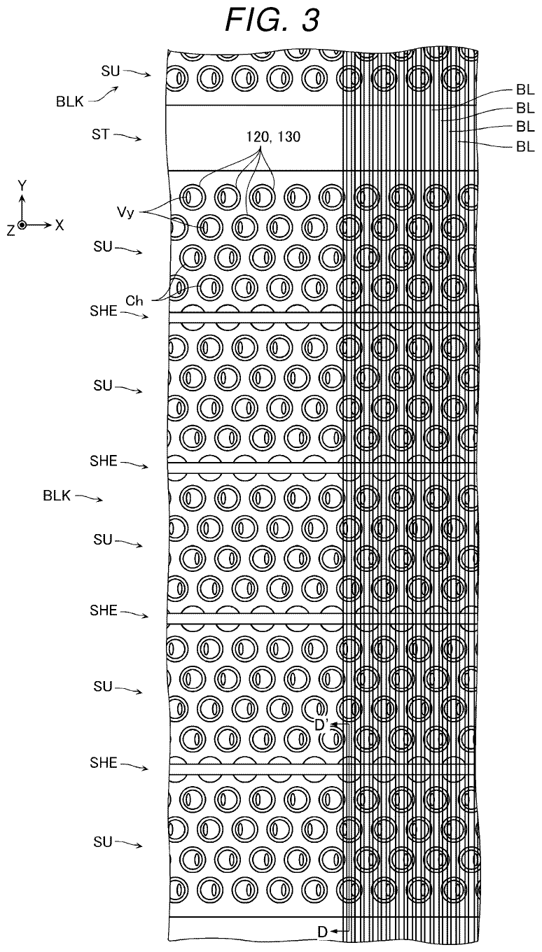

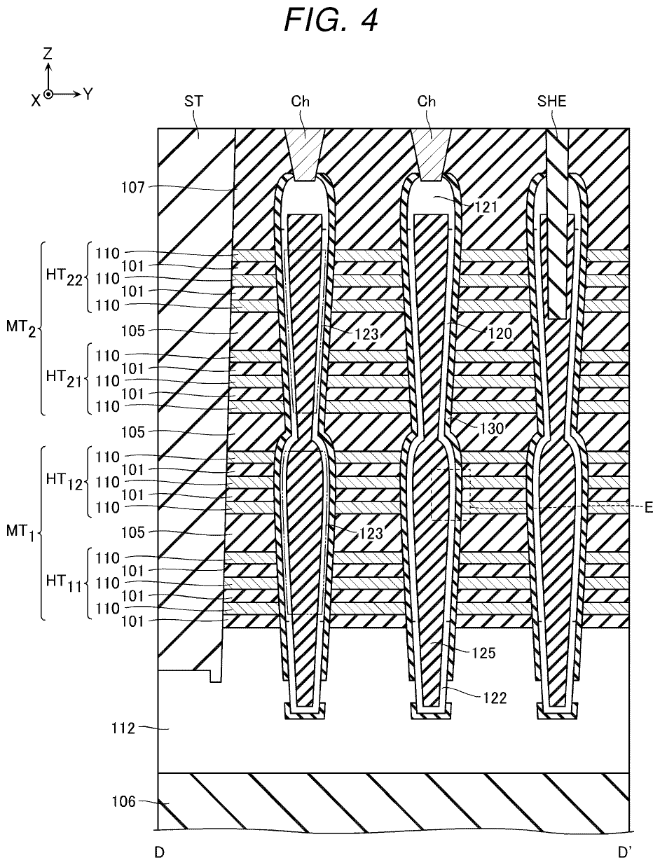

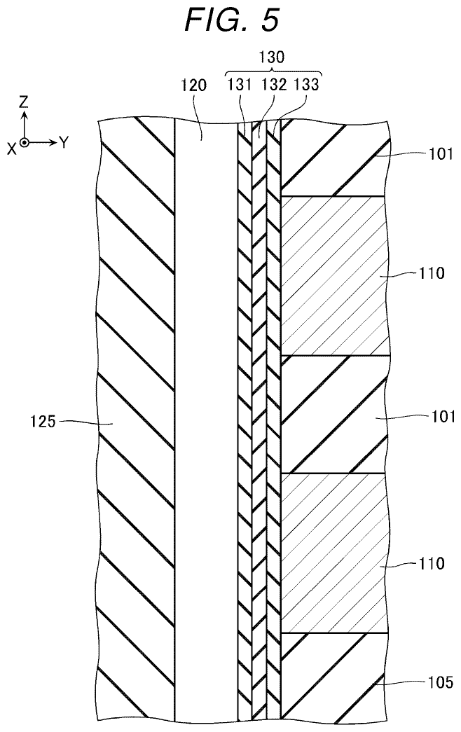

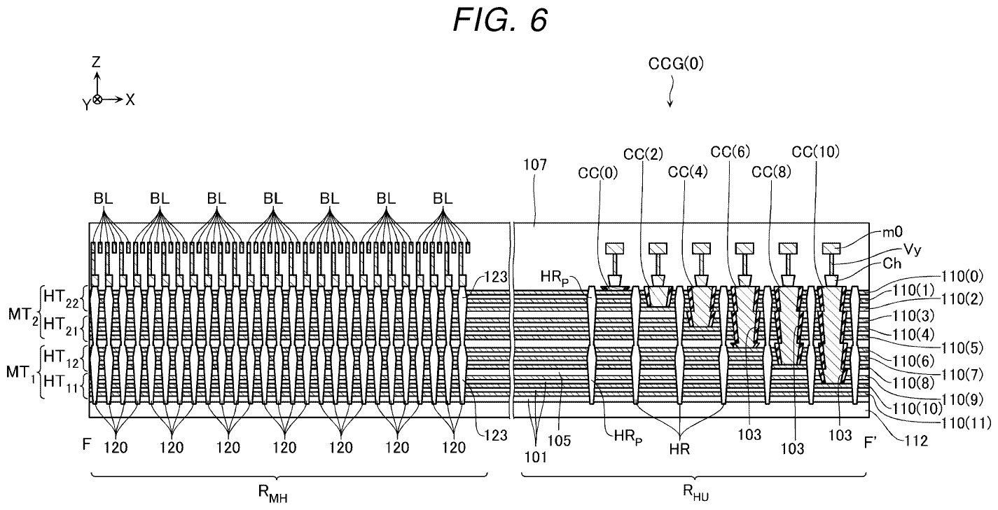

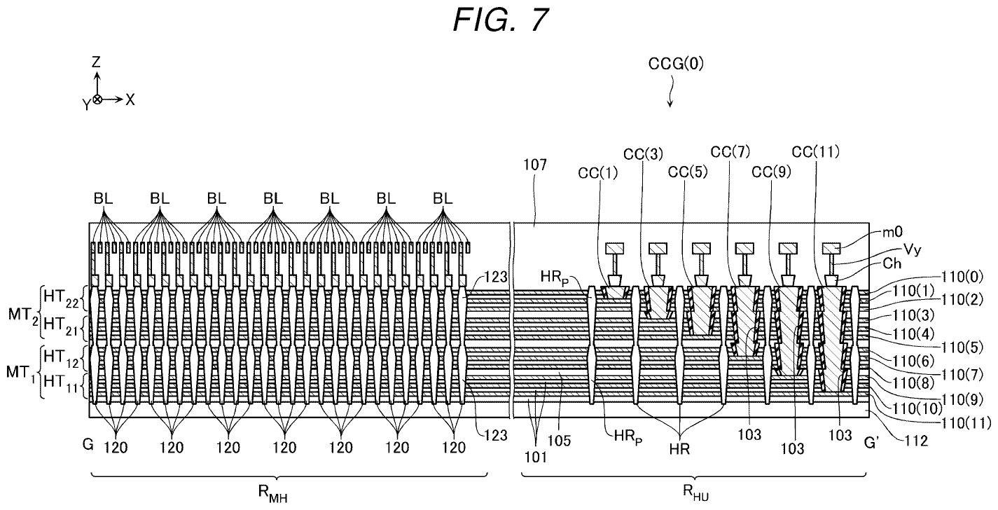

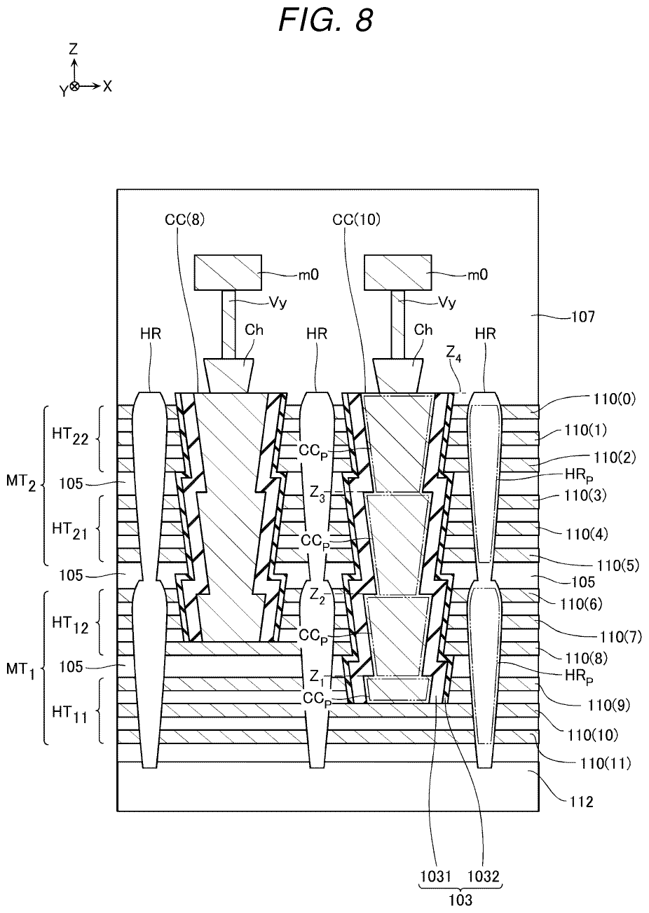

FIG. 1 is a schematic plan view of a memory die MD. FIG. 2 is a schematic enlarged view of a portion indicated by A and a portion indicated by B in FIG. 1. FIG. 3 is a schematic enlarged view of a portion indicated by C in FIG. 2. FIG. 4 is a schematic cross-sectional view when a structure shown in FIG. 3 is taken along line D-D′ and viewed in a direction of an arrow. FIG. 5 is a schematic enlarged view of a portion indicated by E in FIG. 4. FIG. 6 is a schematic cross-sectional view when a structure shown in FIG. 2 is taken along line F-F′ and viewed in a direction of an arrow. FIG. 7 is a schematic cross-sectional view when the structure shown in FIG. 2 is taken along line G-G′ and viewed in a direction of an arrow. FIG. 8 is a schematic cross-sectional view showing an enlarged portion in FIG. 6.

For example, as shown in FIG. 1, the memory die MD includes a semiconductor substrate 100. For example, the semiconductor substrate 100 is a semiconductor substrate including P-type silicon (Si) containing P-type impurities such as boron (B). An N-type well region containing N-type impurities such as phosphorus (P), a P-type well region containing P-type impurities such as boron (B), a semiconductor substrate region in which the N-type well region and the P-type well region are not provided, and an insulating region are provided on a front surface of the semiconductor substrate 100.

In addition, the memory die MD includes four memory cell array regions RMCA arranged in the X-direction and the Y-direction. The memory cell array region RMCA includes two memory hole regions RMH arranged in the X-direction and a hook up region RHU provided between the memory hole regions RMH.

A plurality of memory blocks BLK arranged in the Y-direction are provided in the memory cell array region RMCA. For example, as illustrated in FIG. 2, the memory block BLK includes a plurality of string units SU arranged in the Y-direction. An inter-block insulating layer ST made of silicon oxide (SiO2) or the like is provided between two memory blocks BLK adjacent to each other in the Y-direction. For example, as illustrated in FIG. 3, an inter-string unit insulating layer SHE made of silicon oxide (SiO2) or the like is provided between two string units SU adjacent to each other in the Y-direction.

The memory block BLK includes a plurality of (e.g., two) hierarchical structures MT1 and MT2 arranged in the Z-direction. The hierarchical structure MT1 includes a plurality of (e.g., two) divided structures HT11 and HT12 arranged in the Z-direction. Similarly, the hierarchical structure MT2 includes a plurality of (e.g., two) divided structures HT21 and HT22 arranged in the Z-direction. The plurality of divided structures HT11, HT12, HT21, and HT22 in the memory block BLK each include a plurality of conductive layers 110 and a plurality of insulating layers 101 made of silicon oxide (SiO2) or the like which are alternately arranged in the Z-direction. In addition, insulating layers 105 made of silicon oxide (SiO2) or the like are respectively provided between the plurality of divided structures HT11, HT12, HT21, and HT22 in the memory block BLK. In addition, an insulating layer 107 made of silicon oxide (SiO2) or the like is provided above the uppermost layer divided structure HT22. A thickness of the insulating layer 105 in the Z-direction is larger than a thickness of the insulating layer 101 in the Z-direction. In addition, the thickness of the insulating layer 107 in the Z-direction is larger than the thickness of the insulating layer 105 in the Z-direction.

In addition, the memory hole region RMH of the memory block BLK includes a plurality of semiconductor columns 120 extending in the Z-direction over the plurality of divided structures HT11, HT12, HT21, and HT22, and a plurality of gate insulating films 130 each provided between the plurality of conductive layers 110 and the plurality of semiconductor columns 120.

The conductive layer 110 is a substantially plate-shaped conductive layer extending in the X-direction. The conductive layer 110 may include a stacked film of a barrier conductive film made of titanium nitride (TiN) or the like and a metal film made of tungsten (W) or the like. For example, the conductive layer 110 may contain polycrystalline silicon containing impurities such as phosphorus (P) or boron (B). The conductive layer 110 functions as a gate electrode and a word line of a memory cell or a gate electrode and a select gate line of a select transistor.

A semiconductor layer 112 is provided below the conductive layer 110. For example, the semiconductor layer 112 may contain polycrystalline silicon containing impurities such as phosphorus (P) or boron (B). The insulating layer 101 made of silicon oxide (SiO2) or the like is provided between the semiconductor layer 112 and the conductive layer 110. The semiconductor layer 112 functions as a portion of a source line. An insulating layer 106 made of silicon oxide (SiO2) or the like is provided below the semiconductor layer 112.

For example, as shown in FIG. 3, the semiconductor columns 120 are arranged to have a predetermined pattern in the X-direction and the Y-direction. The semiconductor column 120 functions as a channel region of a plurality of memory cells and select transistors. For example, the semiconductor column 120 is a semiconductor layer made of polycrystalline silicon (Si) or the like. For example, as shown in FIG. 4, the semiconductor column 120 has a substantially cylindrical shape, and an insulating layer 125 made of silicon oxide or the like is provided in a central portion of the semiconductor column 120. An outer peripheral surface of each of the semiconductor columns 120 is surrounded by the conductive layer 110, and faces the conductive layer 110.

An impurity region 121 containing N-type impurities such as phosphorus (P) is provided in an upper end portion of the semiconductor column 120. In an example in FIG. 4, a lower end portion of the impurity region 121 is indicated by a broken line. The impurity region 121 is connected to a bit line BL via a contact electrode Ch and a contact electrode Vy as shown in FIG. 3.

An impurity region 122 containing N-type impurities such as phosphorus (P) is provided in a lower end portion of the semiconductor column 120. In the example in FIG. 4, the upper end portion of the impurity region 122 is indicated by a broken line. The impurity region 122 is connected to the semiconductor layer 112.

In one embodiment, the semiconductor column 120 includes two portions 123 arranged in the Z-direction which corresponds to each of the hierarchical structure MT1 and the hierarchical structure MT2. In the two portions 123, the portion corresponding to the hierarchical structure MT1 is provided from a height position corresponding to a lower surface of the lowermost layer conductive layer 110 provided in the hierarchical structure MT1 to a height position corresponding to an upper surface of the uppermost layer conductive layer 110 provided in the hierarchical structure MT1. In addition, in the two portions 123, the portion corresponding to the hierarchical structure MT2 is provided from a height position corresponding to the lower surface of the lowermost layer conductive layer 110 provided in the hierarchical structure MT2 to a height position corresponding to the upper surface of the uppermost layer conductive layer 110 provided in the hierarchical structure MT2. The widths of the portions 123 in the X-direction and the Y-direction (i.e., the diameter when viewed in the Z-direction) increase from a lower end to the predetermined height position, and decrease from the height position to an upper end. The width or diameter of the upper end portion of the portions 123 is larger than the width or diameter of the lower end portion of the portions 123.

A gate insulating film 130 has a substantially cylindrical shape covering an outer peripheral surface of the semiconductor column 120. For example, as illustrated in FIG. 5, the gate insulating film 130 includes a tunnel insulating film 131, a charge storage film 132, and a block insulating film 133, which are stacked between the semiconductor column 120 and the conductive layer 110. For example, the tunnel insulating film 131 and the block insulating film 133 are insulating films made of silicon oxide (SiO2). For example, the charge storage film 132 is a film made of silicon nitride (Si3N4), which can store charges. The tunnel insulating film 131, the charge storage film 132, and the block insulating film 133 have a substantially cylindrical shape, and extend in the Z-direction along the outer peripheral surface of the semiconductor column 120 except for a contact portion between the semiconductor column 120 and the semiconductor layer 112.

FIG. 5 shows an example in which the gate insulating film 130 includes the charge storage film 132 made of silicon nitride or the like. Meanwhile, for example, the gate insulating film 130 may include a floating gate made of polycrystalline silicon or the like containing N-type or P-type impurities.

For example, as shown in FIG. 2, the hook up region RHU of the memory block BLK includes a portion of the conductive layer 110 and two contact electrode rows CCG (contact electrode regions) arranged in the Y-direction. In FIG. 2, the two contact electrode rows CCG are shown as CCG(0) and CCG(1).

For example, as shown in FIG. 6, the hook up region RHU includes a plurality of support insulating members HR. For example, the support insulating member HR contains silicon oxide (SiO2) or the like. As shown in FIGS. 6 to 8, the support insulating member HR extends in the Z-direction over the plurality of divided structures HT11, HT12, HT21, and HT22, and penetrates the plurality of conductive layers 110 and the insulating layers 101. Each outer peripheral surface of the support insulating members HR is surrounded by at least some of the conductive layers 110.

For example, as shown in FIG. 8, the support insulating member HR includes two portions HRP arranged in the Z-direction which corresponds to each of the hierarchical structure MT1 and the hierarchical structure MT2. In the two portions HRP, a portion corresponding to the hierarchical structure MT1 is provided from a height position corresponding to the lower surface of the lowermost layer conductive layer 110 provided in the hierarchical structure MT1 to a height position corresponding to the upper surface of the uppermost layer conductive layer 110 provided in the hierarchical structure MT1. In addition, in the two portions HRP, a portion corresponding to the hierarchical structure MT2 is provided from a height position corresponding to the lower surface of the lowermost layer conductive layer 110 provided in the hierarchical structure MT2 to a height position corresponding to the upper surface of the uppermost layer conductive layer 110 provided in the hierarchical structure MT2. The widths of the portions HRP in the X-direction and the Y-direction (i.e., the diameter when viewed in the Z-direction) increase from the lower end to a predetermined height position, and decrease from the height position to the upper end. The width or diameter of the upper end portion of the portions HRP is larger than the width or diameter of the lower end portion of the portions HRP. A height position where the widths of the portions HRP in the X-direction and the Y-direction are maximized substantially coincides with a height position where the width of the portion 123 in the X-direction and the Y-direction is maximized. The width or diameter of the upper end portion of the portions HRP is larger than the width or diameter of the lower end portion.

In the hierarchical structure MT1 and the hierarchical structure MT2, the height position of the portion HRP of the support insulating member HR having the largest width or diameter in the Z-direction substantially coincides with the height position of the portion HRP of the semiconductor column 120 having the largest width or diameter in the Z-direction.

As shown in FIGS. 6 and 7, a contact electrode row CCG includes a plurality of contact electrodes CC arranged in the X-direction. The plurality of contact electrodes CC extend in the Z-direction over the plurality of divided structures HT11, HT12, HT21, and HT22, penetrate the plurality of conductive layers 110 and the insulating layers 101, and are connected to the conductive layers 110 in the lower end. For example, the contact electrode CC may include a stacked film of a barrier conductive film made of titanium nitride (TiN) or the like and a metal film made of tungsten (W) or the like. In addition, an insulating layer 103 is provided on an outer peripheral surface of the contact electrode CC.

In the following description, the n-th (n is an integer of 1 or more) conductive layer 110 counted from above may be referred to as a conductive layer 110(n-1). In addition, in the plurality of contact electrodes CC, the contact electrode CC connected to the conductive layer 110(n) may be referred to as a contact electrode CC(n).

As shown in FIG. 6, the contact electrode row CCG(0) includes contact electrodes CC(0), CC(2), CC(4), CC(6), CC(8), and CC(10) in order from the contact electrode close to the memory hole region RMH.

As shown in FIG. 7, the contact electrode row CCG(1) includes contact electrodes CC(1), CC(3), CC(5), CC(7), CC(9), and CC(11) in order from the contact electrode close to the memory hole region RMH.

As shown in FIG. 2, the plurality of contact electrodes CC(0), CC(2), CC(4), CC(6), CC(8), and CC(10) in the contact electrode row CCG(0) are respectively arranged in the Y-direction with the plurality of contact electrodes CC(1), CC(3), CC(5), CC(7), and CC(11) in the contact electrode row CCG(1).

For example, as shown in FIG. 8, the contact electrode CC(10) includes four portions CCP arranged in the Z-direction to correspond to each of the divided structures HT11, HT12, HT21, and HT22. In the four portions CCP, a portion corresponding to the divided structure HT11 is provided from the lower end of the contact electrode CC(10) to a predetermined height position Z1 below the lower surface of the lowermost layer conductive layer 110 provided in the divided structure HT12. In the four portions CCP, a portion corresponding to the divided structure HT12 is provided from the height position Z1 to a predetermined height position Z2 below the lower surface of the lowermost layer conductive layer 110 provided in the divided structure HT21. In the four portions CCP, a portion corresponding to the divided structure HT21 is provided from the height position Z2 to a predetermined height position Z3 below the lower surface of the lowermost layer conductive layer 110 provided in the divided structure HT22. In the four portions CCP, a portion corresponding to the divided structure HT22 is provided from the height position Z3 to a predetermined height position Z4 above the upper surface of the uppermost layer conductive layer 110 provided in the divided structure HT22. The widths of the portions CCP in the X-direction and the Y-direction (i.e., the diameter when viewed in the Z-direction) increase from the lower end to the upper end. The width or diameter of the upper end portion of the portions CCP is larger than the width or diameter of the lower end portion of the portions CCP. The height position where the width of the portion CCP in the X-direction and the Y-direction are maximized (i.e., the height position of the upper end of the portion CCP) is different from the height position where the widths of the portions 123 and HRP in the X-direction and the Y-direction are maximized.

The other contact electrodes CC(9) and CC(11) corresponding to the conductive layers 110(9), 110(10), and 110(11) in the divided structure HT11 also have the same structure as the contact electrode CC(10).

The contact electrodes CC(6), CC(7), and CC(8) corresponding to the conductive layers 110(6), 110(7), and 110(8) in the divided structure HT12 have substantially the same structure as the contact electrodes CC(9), CC(10), and CC(11). The contact electrodes CC(6), CC(7), and CC(8) do not include the portion CCP corresponding to the divided structure HT11. In addition, in the three portions CCP provided in the contact electrodes CC(6), CC(7), and CC(8), a portion corresponding to the divided structure HT12 is provided from the lower end of the contact electrodes CC(6), CC(7), and CC(8) to the height position Z2.

The contact electrodes CC(3), CC(4), and CC(5) corresponding to the conductive layers 110(3), 110(4), and 110(5) in the divided structure HT21 have substantially the same structure as the contact electrodes CC(6), CC(7), and CC(8). The contact electrodes CC(3), CC(4), and CC(5) do not include the portion CCP corresponding to the divided structure HT12. In addition, in the two portions CCP provided in the contact electrodes CC(3), CC(4), and CC(5), a portion corresponding to the divided structure HT21 is provided from the lower end of the contact electrodes CC(3), CC(4), and CC(5) to the height position Z3.

The contact electrodes CC(0), CC(1), and CC(2) corresponding to the conductive layers 110(0), 110(1), and 110(2) in the divided structure HT22 have substantially the same structure as the contact electrodes CC(3), CC(4), and CC(5). The contact electrodes CC(0), CC(1), and CC(2) do not include the portion CCP corresponding to the divided structure HT21. In addition, the portion CCP provided in the contact electrodes CC(0), CC(1), and CC(2) is provided from the lower end of the contact electrodes CC(0), CC(1), and CC(2) to the height position Z4.

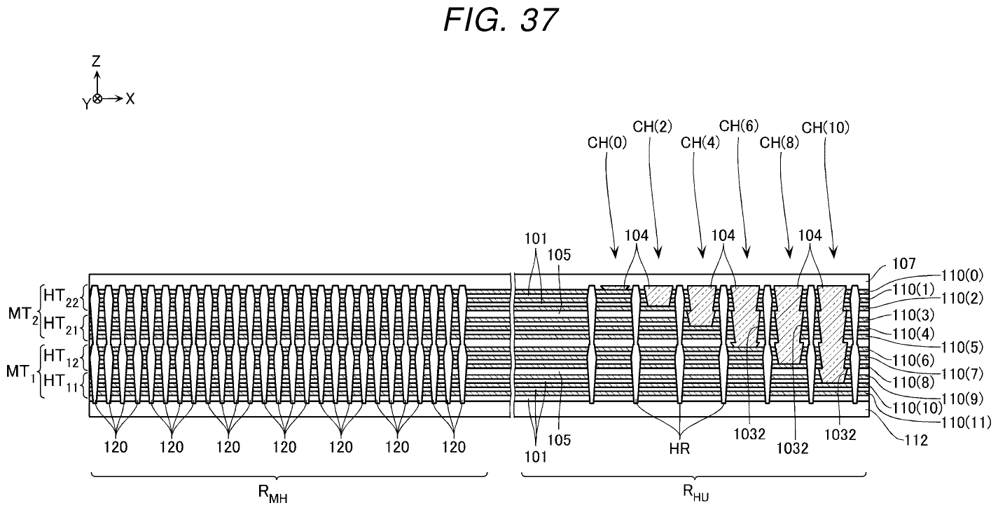

The insulating layer 103 has a substantially cylindrical shape covering the outer peripheral surface of the contact electrode CC when viewed in the Z-direction. For example, as shown in FIG. 8, the insulating layer 103 includes a spacer oxide film 1031 and a block oxide film 1032 which are stacked between the contact electrode CC and the conductive layer 110. For example, the spacer oxide film 1031 and the block oxide film 1032 contain silicon oxide (SiO2). The spacer oxide film 1031 is a film for holding a breakdown voltage between the contact electrode CC and the conductive layer 110 (i.e., word line). The block oxide film 1032 is a film for protecting a configuration in a contact hole CH in a manufacturing step to be described later with reference to FIG. 37, and has phosphoric acid resistance, for example. The spacer oxide film 1031 and the block oxide film 1032 have a substantially cylindrical shape, and extend in the Z-direction along the outer peripheral surface of the semiconductor column 120 except for a contact portion between the contact electrode CC and the semiconductor layer 112.

A film thickness of the spacer oxide film 1031 is larger than a film thickness of the block oxide film 1032. For example, the spacer oxide film 1031 and the block oxide film 1032 have hydrogen contents which are different from each other. For example, etching rates of the spacer oxide film 1031 and the block oxide film 1032 are different from each other. The content of nitrogen (N) in the block oxide film 1032 is higher than the content of nitrogen (N) in the spacer oxide film 1031.

### Manufacturing Method

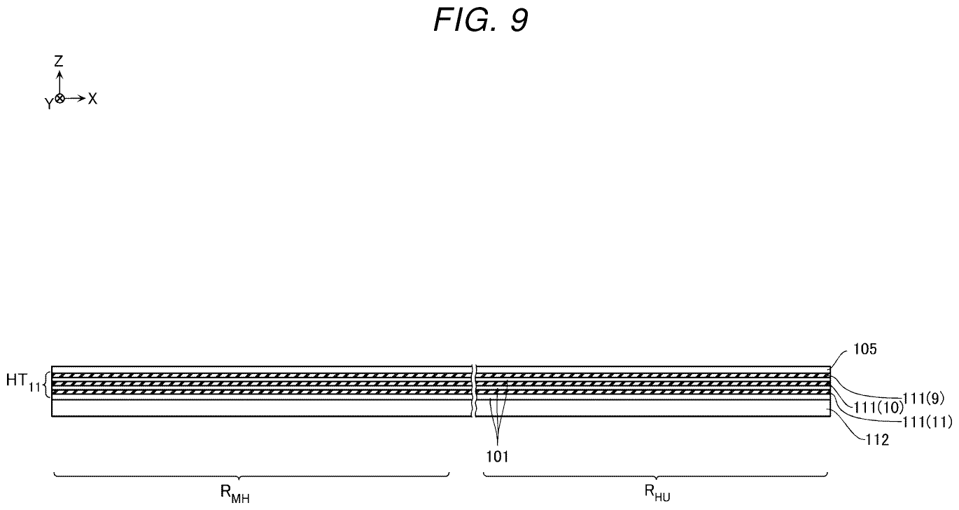

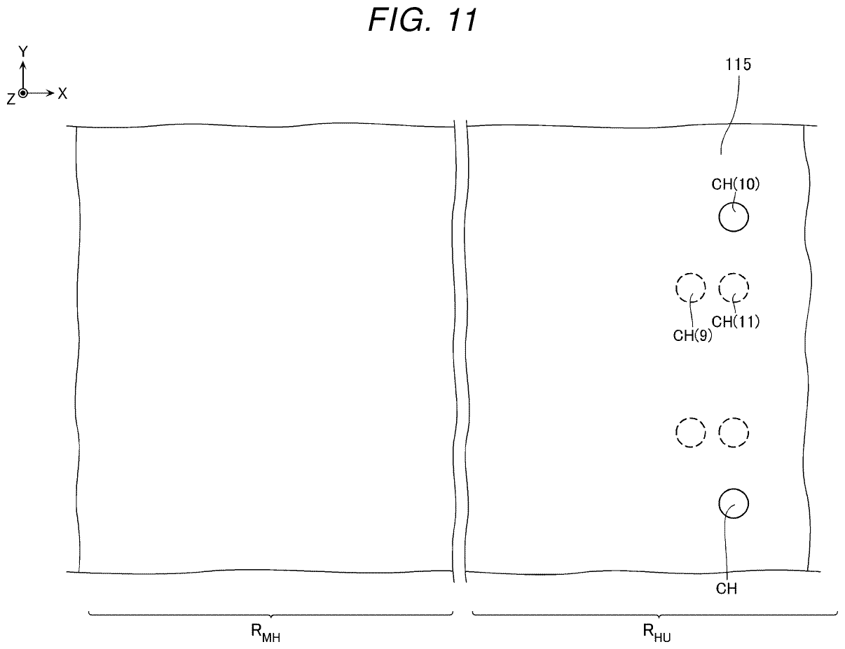

Next, a manufacturing method of the memory die MD will be described with reference to FIGS. 9 to 41. FIGS. 11, 16, 24, and 29 are schematic plan views illustrating the manufacturing method, and show planes corresponding to FIG. 2. FIGS. 9, 10, 12 to 15, 17 to 23, 25 to 28, and 30 to 41 are schematic cross-sectional views illustrating the manufacturing method, and show cross sections corresponding to FIG. 6.

When the memory die MD is manufactured, for example, as shown in FIG. 9, the semiconductor layer 112 is formed. In addition, a plurality of insulating layers 101 and a plurality of sacrificial layers 111 which correspond to the divided structure HT11 are alternately formed above the semiconductor layer 112. For example, the sacrificial layer 111 contains silicon nitride (Si3N4). In addition, the insulating layer 105 is formed above the uppermost layer sacrificial layer 111. For example, this step is performed by a method such as chemical vapor deposition (CVD). In the following description, the sacrificial layer 111 corresponding to the n-th (n is an integer of 1 or more) conductive layer 110(n-1) counted from above may be referred to as a sacrificial layer 111(n-1).

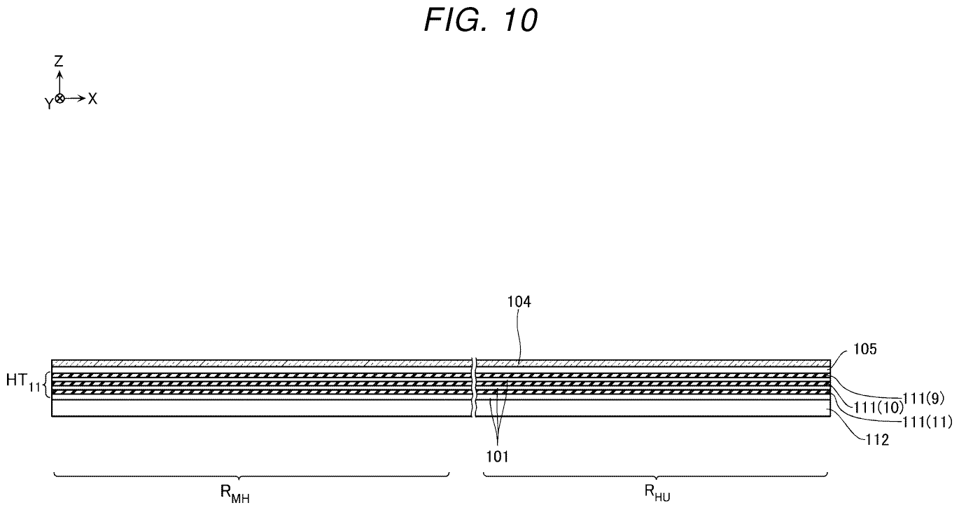

Next, for example, as shown in FIG. 10, a cover layer 104 which is a sacrificial layer of amorphous silicon (aSi) is formed on an upper surface of the structure described with reference to FIG. 9. For example, this step is performed by a method such as CVD.

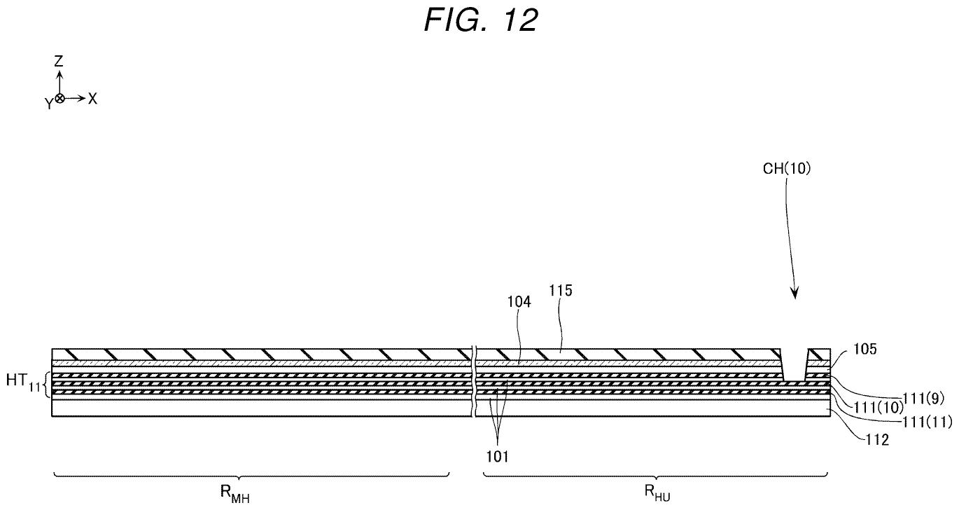

Next, for example, as shown in FIGS. 11 and 12, the contact hole CH is formed at a position corresponding to a portion in the contact electrodes CC. In the following description, in the contact holes CH, the contact hole CH that exposes the upper surface of the sacrificial layer 111(n) and penetrates all of the sacrificial layers 111 provided above the upper surface of the sacrificial layer 111(n) may be referred to as a contact hole CH(n).

In this step, for example, a resist is formed on an upper surface of the cover layer 104. The resist exposes the upper surface of the cover layer 104 at a position corresponding to the contact electrodes (e.g., CC(9), CC(10), and CC(11) in the drawings) corresponding to the divided structure HT11 in the plurality of contact electrodes CC. Next, the cover layer 104 and the insulating layer 105 are removed by a method such as reactive ion etching (RIE), and the upper surface of the uppermost layer sacrificial layer 111 (e.g., the sacrificial layer 111(9) in the drawings) is exposed. In this step, the contact hole CH(9) is formed at a height position corresponding to the divided structure HT11.

Next, the resist is removed to form a resist 115 shown in FIG. 12. The resist 115 exposes the upper surface of the uppermost layer sacrificial layer 111(9) at a position corresponding to the contact electrode (e.g., the contact electrode CC(10) in the drawings) corresponding to the (2a+2)-th (a is an integer of 0 or more) sacrificial layer 111 (e.g., the sacrificial layer 111(10) in the drawings) counted from above in the plurality of contact electrodes CC corresponding to the divided structure HT11. Next, one sacrificial layer 111 and the insulating layer 101 provided on the lower surface of the sacrificial layer 111 are removed by a method such as RIE, and the upper surface of the (2a+2)-th sacrificial layer 111 is exposed. In this step, a contact hole CH (10) is formed at a height position corresponding to the divided structure HT11.

Next, the resist 115 is removed to further form a resist. The resist exposes the upper surface of the (2a+2)-th sacrificial layer 111 at a position corresponding to the contact electrode CC (e.g., the contact electrodes CC(11) in the drawings) corresponding to the (4a+3)-th and (4a+4)-th (a is an integer of 0 or more) sacrificial layers 111 (e.g., the sacrificial layer 111(11) in the drawings) counted from above in the plurality of contact electrodes CC corresponding to the divided structure HT11. Next, the two sacrificial layers 111 and the two insulating layers 101 respectively provided on the lower surfaces of the two sacrificial layers 111 are removed by a method such as RIE, and the upper surfaces of the sacrificial layers 111 are exposed. In this step, a contact hole CH(11) is formed at a height position corresponding to the divided structure HT11.

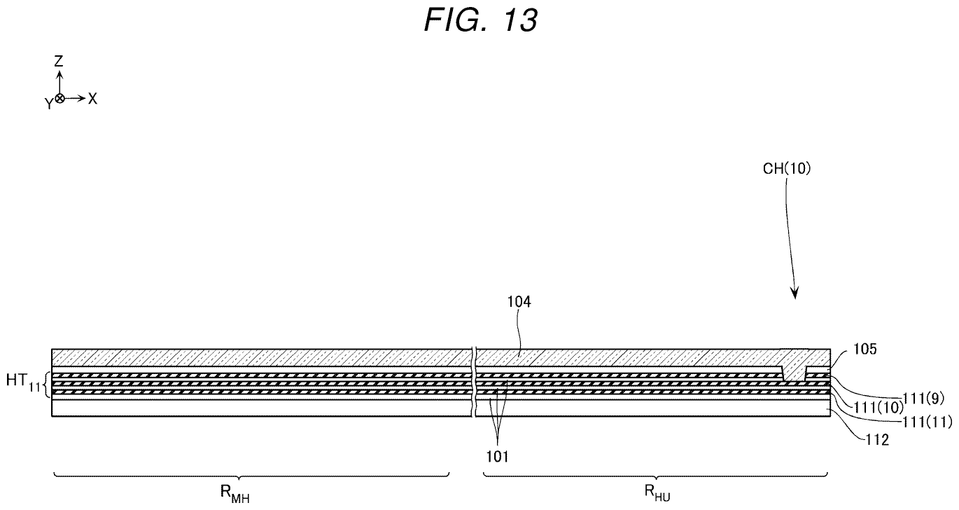

Next, for example, as shown in FIG. 13, the resist is removed to further form the cover layer 104 made of amorphous silicon (aSi) on the upper surface of the cover layer 104, and the contact hole CH is embedded. For example, this step is performed by a method such as CVD.

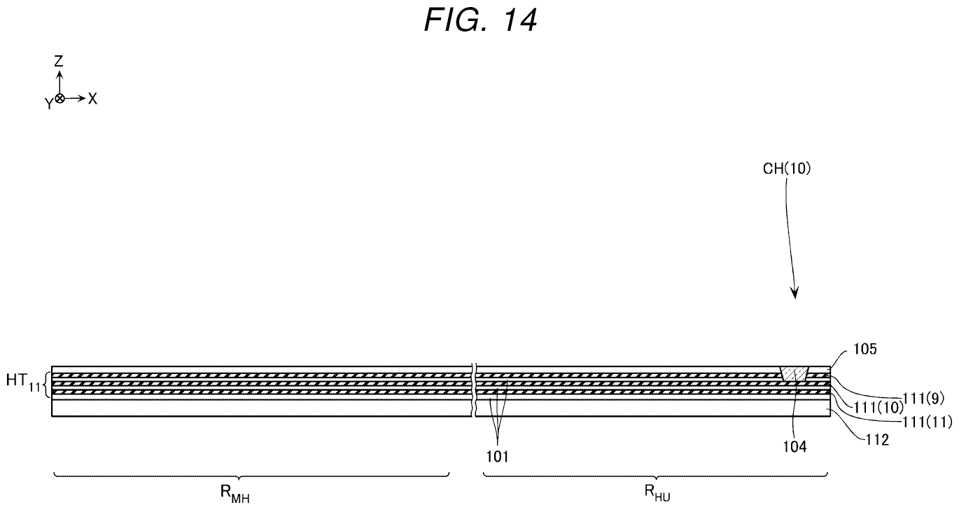

Next, for example, as shown in FIG. 14, a portion of the cover layer 104 is removed to expose the upper surface of the insulating layer 105. For example, this step is performed by a flattening process such as chemical mechanical polishing (CMP).

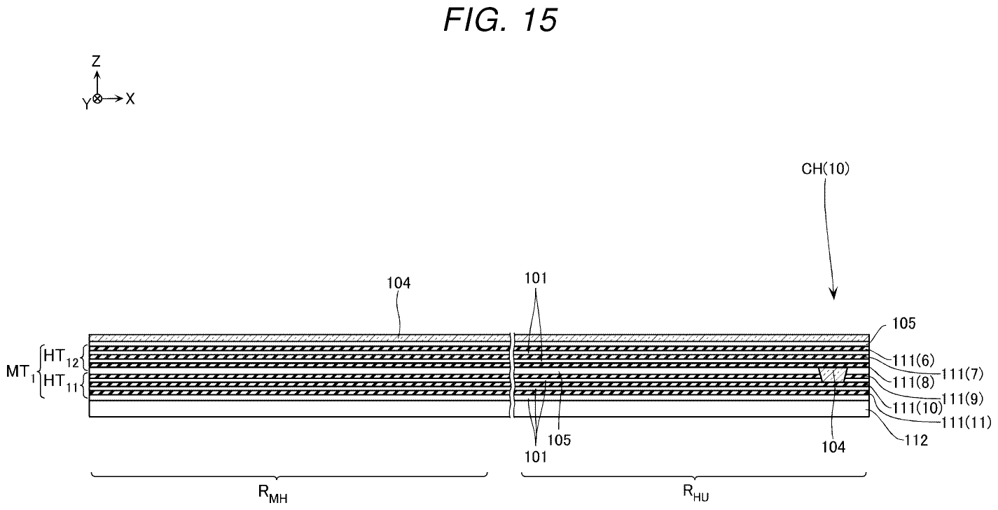

Next, for example, as shown in FIG. 15, the plurality of insulating layers 101 and the plurality of sacrificial layers 111 which correspond to the divided structure HT12 are alternately formed on the upper surface of the insulating layer 105. In addition, the insulating layer 105 and the cover layer 104 are formed above the uppermost layer sacrificial layer 111. For example, this step is performed by a method such as CVD.

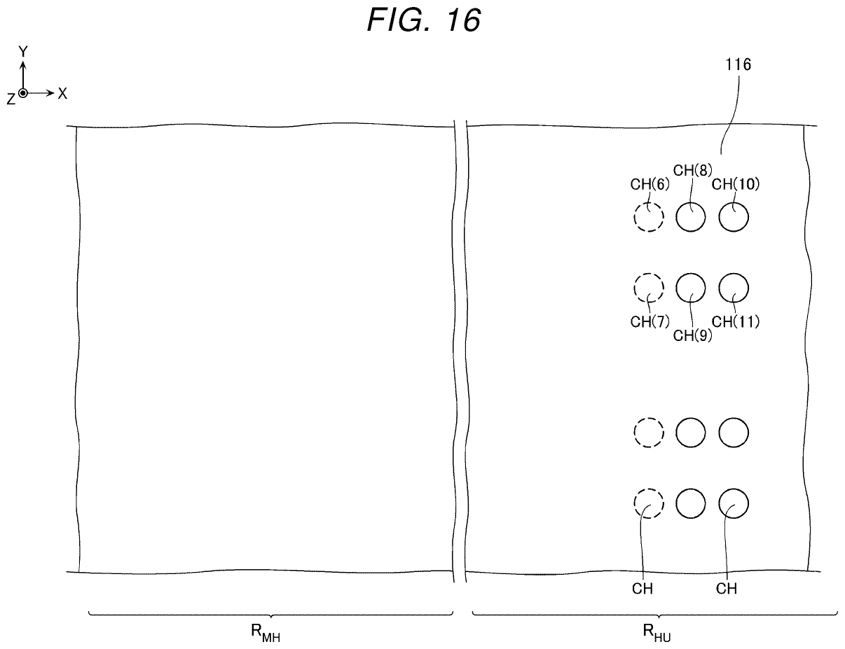

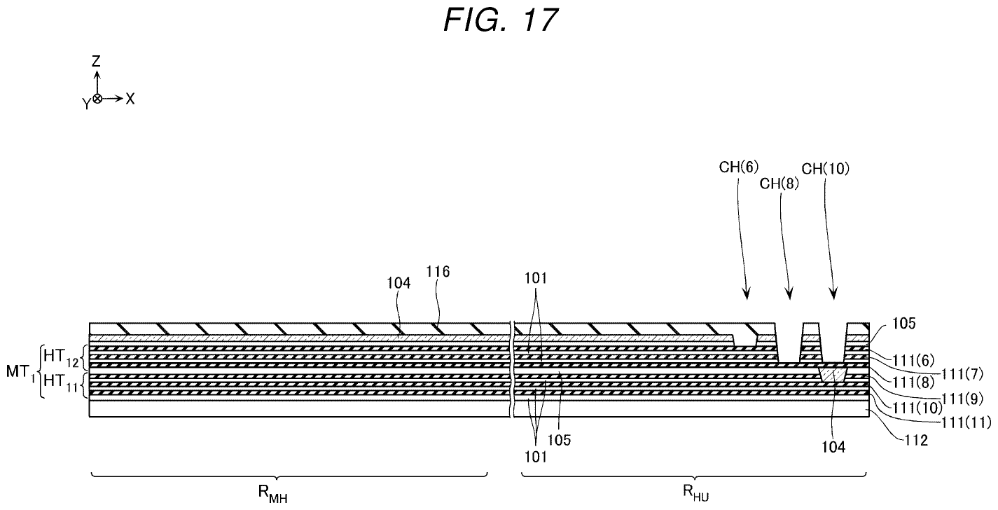

Next, for example, as shown in FIGS. 16 and 17, the contact hole CH is formed at a position corresponding to a portion in the contact electrode CC.

In this step, for example, the resist is first formed on the upper surface of the cover layer 104. The resist exposes the upper surface of the cover layer 104 at a position corresponding to the contact electrode CC corresponding to the sacrificial layer 111 in the divided structures HT11 and HT12 in the plurality of contact electrodes CC. Next, the cover layer 104 and the insulating layer 105 are removed by a method such as RIE, and the upper surface of the uppermost layer sacrificial layer 111(6) is exposed. In this step, a contact hole CH(6) is formed at a height position corresponding to the divided structure HT12.

Next, the resist is removed to further form a resist. The resist exposes the upper surface of the uppermost layer sacrificial layer 111(6) at a position corresponding to the plurality of contact electrodes CC corresponding to the sacrificial layer 111 in the divided structure HT11. In addition, the resist exposes the upper surface of the uppermost layer sacrificial layer 111(6) at a position corresponding to the contact electrode CC corresponding to the (2a+2)-th (a is an integer of 0 or more) sacrificial layer 111 counted from above in the plurality of contact electrodes CC corresponding to the divided structure HT12. Next, one sacrificial layer 111 and the insulating layer 101 provided on the lower surface of the sacrificial layer 111 are removed by a method such as RIE, and the upper surface of the (2a+2)-th sacrificial layer 111 is exposed. In this step, a contact hole CH(7) is formed at a height position corresponding to the divided structure HT12.

Next, the resist is removed to form a resist 116. The resist 116 exposes the upper surface of the uppermost layer sacrificial layer 111(6) at a position corresponding to the plurality of contact electrodes CC corresponding to the sacrificial layer 111 in the divided structure HT11. In addition, the resist 116 exposes the upper surface of the sacrificial layer 111 at a position corresponding to the contact electrode CC corresponding to the (4a+3)-th and (4a+4)-th (a is an integer of 0 or more) sacrificial layers 111 counted from above in the plurality of contact electrodes CC corresponding to the divided structure HT₁₂. Next, the two sacrificial layers 111 and the two insulating layers 101 respectively provided on the lower surfaces of the two sacrificial layers 111 are removed by a method such as RIE, and the upper surfaces of the sacrificial layers 111 are exposed. In this step, a contact hole CH(8) is formed at a height position corresponding to the divided structure HT12.

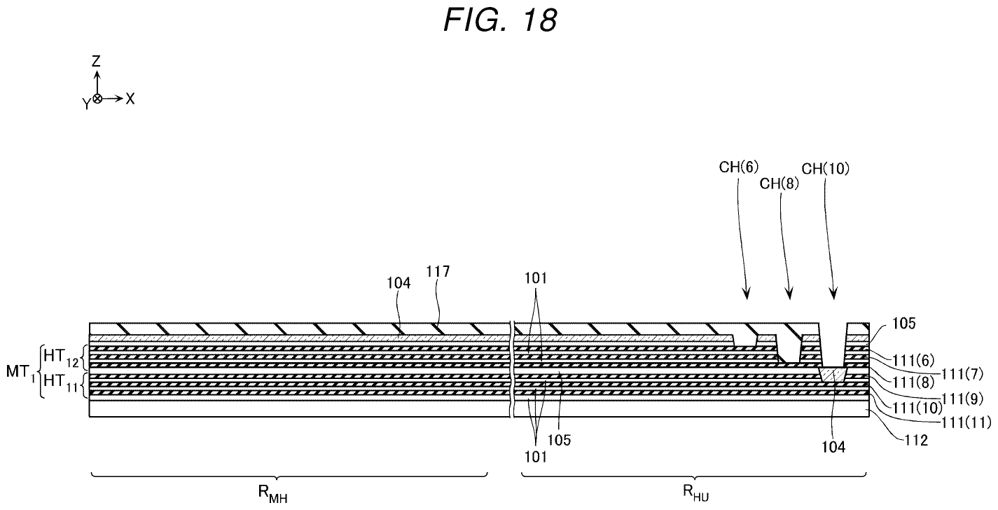

Next, for example, as shown in FIG. 18, the resist 116 is removed to form a resist 117. The resist 117 exposes the upper surface of the lowermost layer sacrificial layer 111(7) in the divided structure HT12 at a position corresponding to the plurality of contact electrodes CC corresponding to the sacrificial layer 111 in the divided structure HT11. Next, one sacrificial layer 111 is removed by a method such as RIE, and the upper surface of the cover layer 104 in the divided structure HT11 is exposed. In this step, the plurality of contact holes CH corresponding to the sacrificial layer 111 in the divided structure HT11 are formed at a height position corresponding to the divided structure HT12.

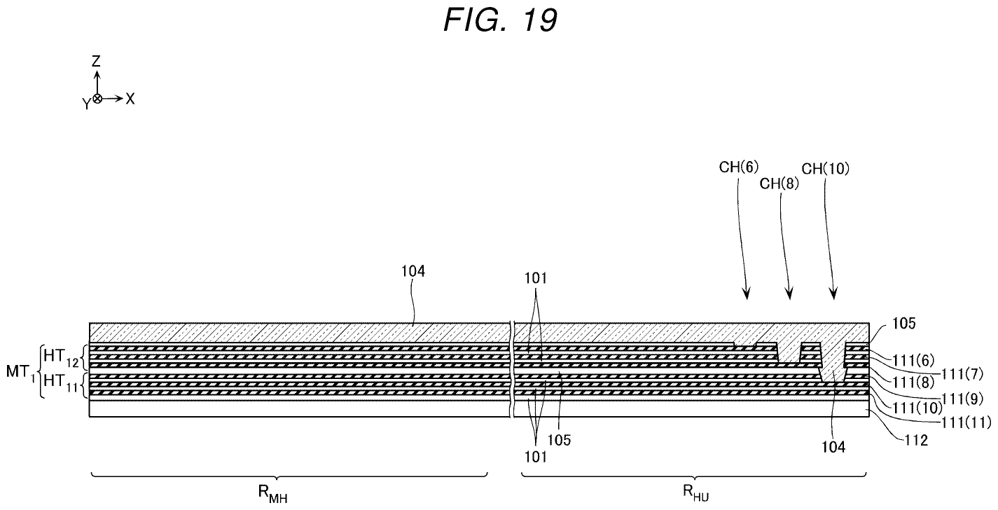

Next, for example, as shown in FIG. 19, the resist 117 is removed to further form the cover layer 104 on the upper surface of the cover layer 104, and the contact hole CH is embedded. For example, this step is performed by a method such as CVD.

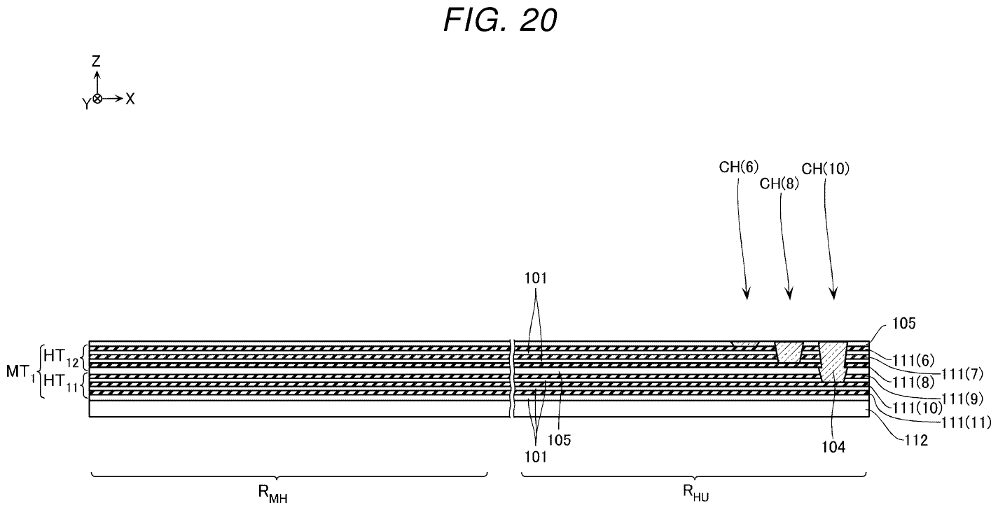

Next, for example, as shown in FIG. 20, a portion of the cover layer 104 is removed to expose the upper surface of the insulating layer 105. For example, this step is performed by a flattening process such as CMP.

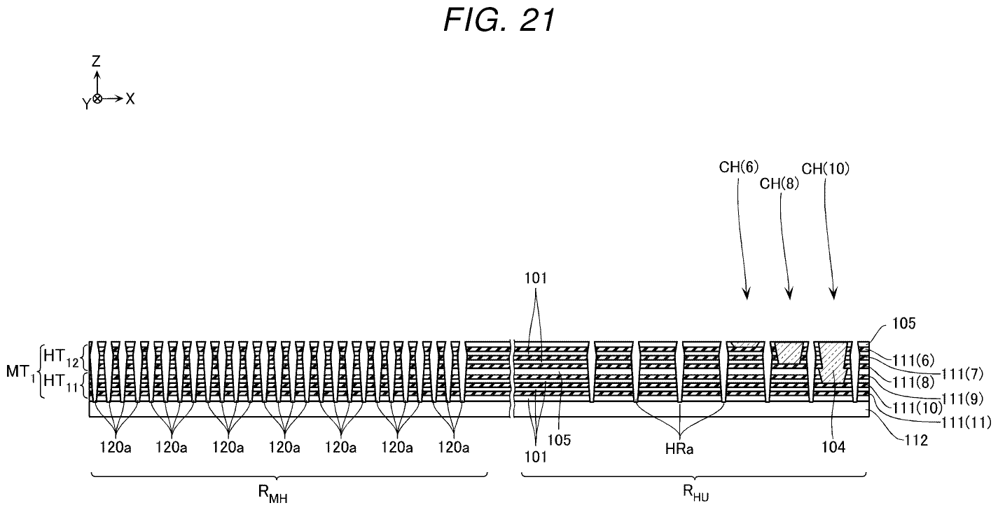

Next, for example, as shown in FIG. 21, a plurality of through-holes 120a are formed at positions corresponding to the plurality of semiconductor columns 120. In addition, a plurality of through-holes HRa are formed at positions corresponding to the plurality of support insulating members HR. The through-holes 120a and HRa each penetrate the plurality of insulating layers 101 and the plurality of sacrificial layers 111 which are provided in the hierarchical structure MT1, extend in the Z-direction, and expose the upper surface of the semiconductor layer 112. For example, this step is performed by a method such as RIE.

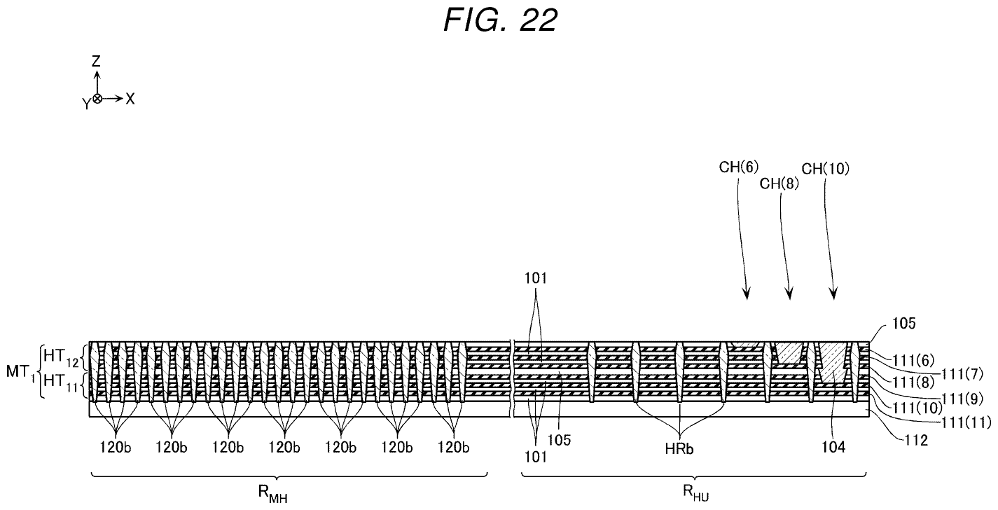

Next, for example, as shown in FIG. 22, the sacrificial layers 120b and HRb made of carbon, for example, are formed in the through-holes 120a and HRa. For example, this step is performed by a method such as plasma CVD.

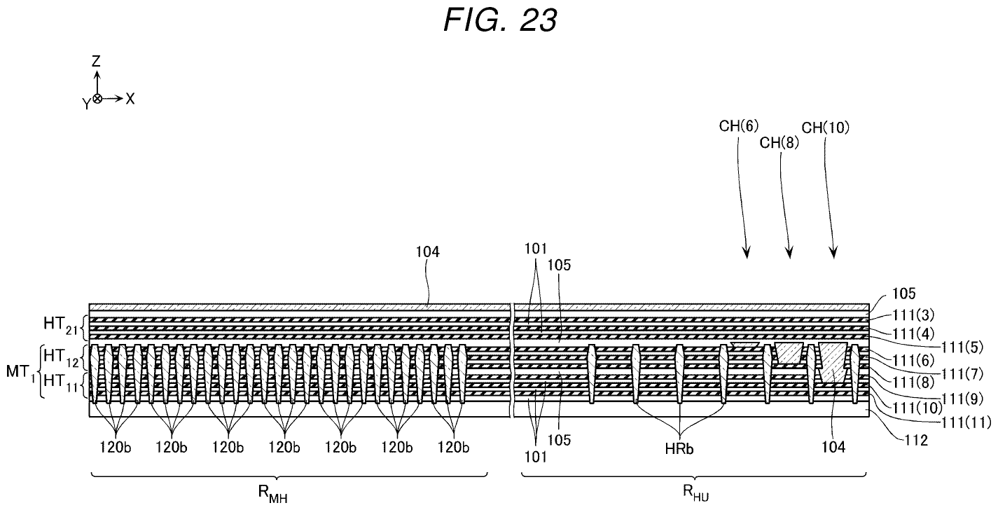

Next, for example, as shown in FIG. 23, the insulating layer 105 is further formed on the upper surface of the insulating layer 105 described with reference to FIG. 22. In addition, the plurality of insulating layers 101 and the plurality of sacrificial layers 111 which correspond to the divided structure HT21 are alternately formed on the upper surface of the insulating layer 105. In addition, the insulating layer 105 and the cover layer 104 are formed above the uppermost layer sacrificial layer 111. For example, this step is performed by a method such as CVD.

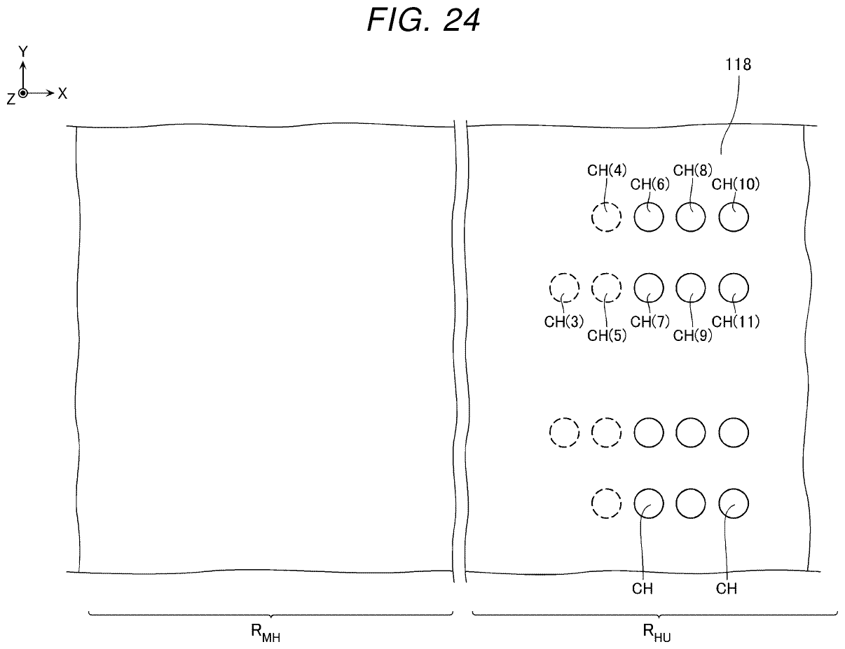

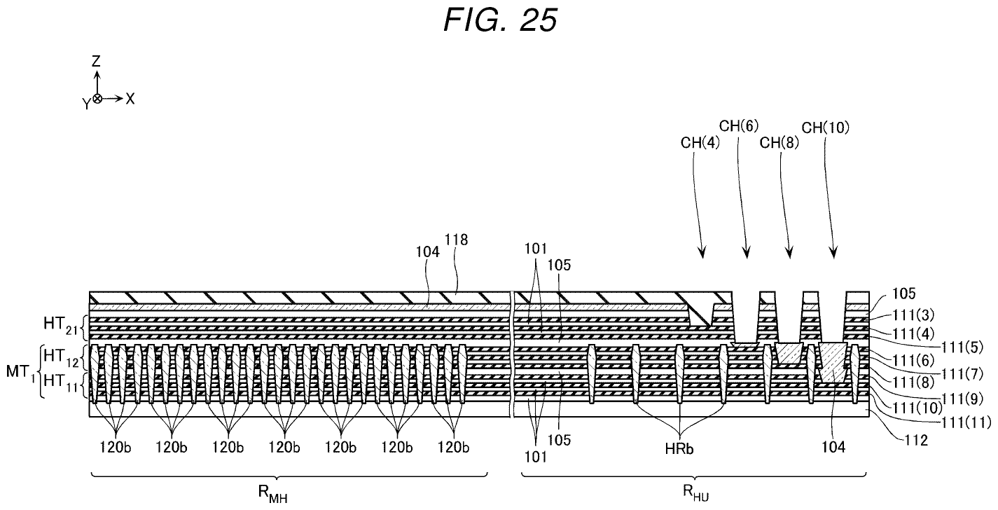

Next, for example, as shown in FIGS. 24 and 25, the contact hole CH is formed at a position corresponding to a portion in the contact electrode CC.

In this step, for example, the resist is first formed on the upper surface of the cover layer 104. The resist exposes the upper surface of the cover layer 104 at a position corresponding to the contact electrode CC corresponding to the sacrificial layer 111 in the divided structures HT11, HT12, and HT21 in the plurality of contact electrodes CC. Next, the cover layer 104 and the insulating layer 105 are removed by a method such as RIE, and the upper surface of the uppermost layer sacrificial layer 111(3) is exposed. In this step, a contact hole CH(3) is formed at a height position corresponding to the divided structure HT21.

Next, the resist is removed to further form a resist. The resist exposes the upper surface of the uppermost layer sacrificial layer 111(3) at positions corresponding to the plurality of contact electrodes CC corresponding to the sacrificial layer 111 in the divided structures HT11 and HT12. In addition, the resist exposes the upper surface of the uppermost layer sacrificial layer 111(3) at a position corresponding to the contact electrode CC corresponding to the (2a+2)-th (a is an integer of 0 or more) sacrificial layer 111 counted from above in the plurality of contact electrodes CC corresponding to the divided structure HT21. Next, one sacrificial layer 111 and the insulating layer 101 provided on the lower surface of the sacrificial layer 111 are removed by a method such as RIE, and the upper surface of the (2a+2)-th sacrificial layer 111 is exposed. In this step, a contact hole CH(4) is formed at a height position corresponding to the divided structure HT21.

Next, the resist is removed to further form a resist. The resist exposes the upper surface of the sacrificial layer 111 at positions corresponding to the plurality of contact electrodes CC corresponding to the sacrificial layer 111 in the divided structures HT11 and HT12. In addition, the resist exposes the upper surface of the sacrificial layer 111 at a position corresponding to the contact electrode CC corresponding to the (4a+3)-th and the (4a+4)-th (a is an integer of 0 or more) sacrificial layers 111 counted from above in the plurality of contact electrodes CC corresponding to the divided structure HT21. Next, the two sacrificial layers 111 and the two insulating layers 101 respectively provided on the lower surfaces of the two sacrificial layers 111 are removed by a method such as RIE, and the upper surfaces of the sacrificial layers 111 are exposed. In this step, a contact hole CH(5) is formed at a height position corresponding to the divided structure HT21. In addition, the plurality of contact holes CH corresponding to the sacrificial layer 111 in the divided structures HT11 and HT12 are formed at height positions corresponding to the divided structure HT21.

Next, the resist is removed to form a resist 118. The resist 118 exposes the upper surface of the lowermost layer sacrificial layer 111(5) in the divided structure HT21 at positions corresponding to the plurality of contact electrodes CC corresponding to the sacrificial layer 111 in the divided structures HT11 and HT12. Next, one sacrificial layer 111 and the insulating layer 105 are removed by a method such as RIE, and the upper surface of the cover layer 104 in the divided structure HT12 is exposed. In this step, the plurality of contact holes CH corresponding to the sacrificial layer 111 in the divided structures HT11 and HT12 are formed at height positions corresponding to the divided structure HT21.

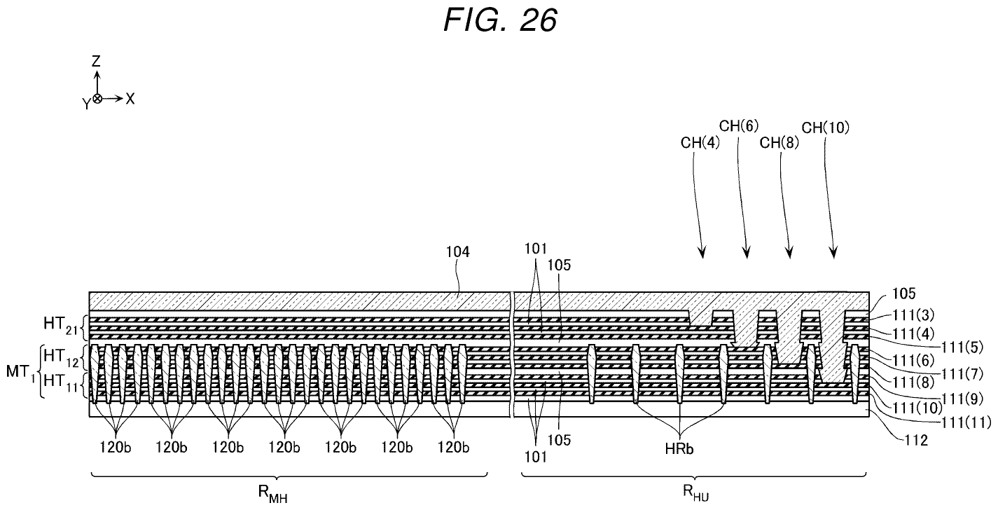

Next, for example, as shown in FIG. 26, the resist 118 is removed to further form the cover layer 104 on the upper surface of the cover layer 104, and the contact hole CH is embedded. For example, this step is performed by a method such as CVD.

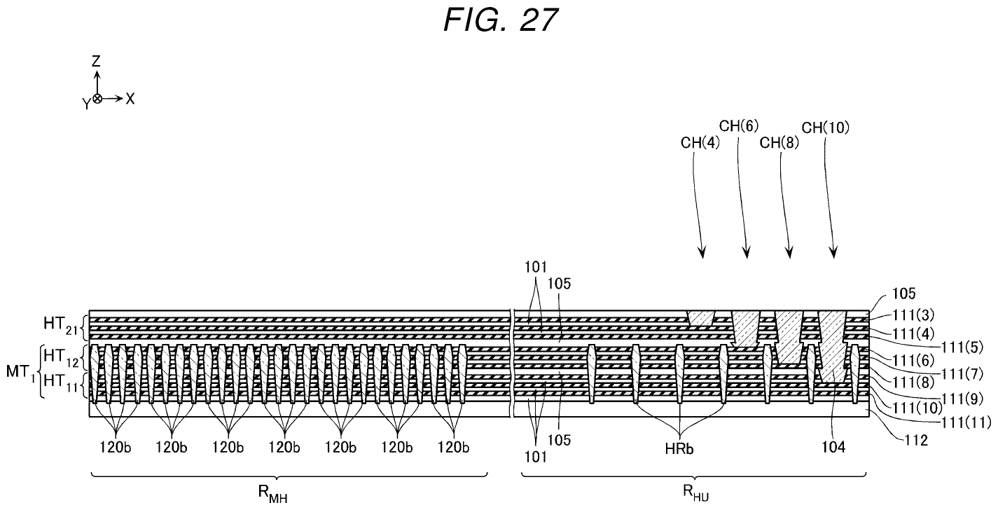

Next, for example, as shown in FIG. 27, a portion of the cover layer 104 is removed to expose the insulating layer 105. For example, this step is performed by a flattening process such as CMP.

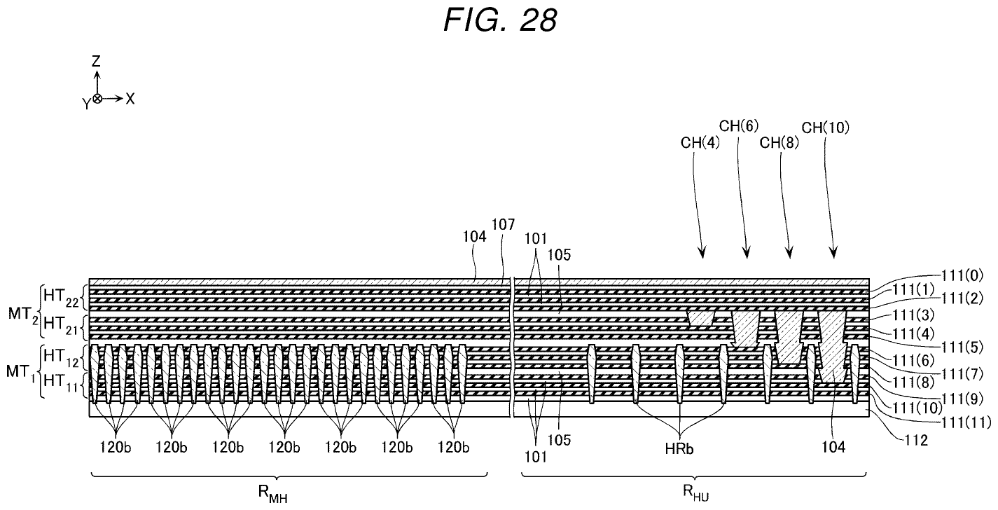

Next, for example, as shown in FIG. 28, the plurality of insulating layers 101 and the plurality of sacrificial layers 111 which correspond to the divided structure HT22 are alternately formed on the upper surface of the insulating layer 105. In addition, a portion of the insulating layer 107 and the cover layer 104 are formed above the uppermost layer sacrificial layer 111. For example, this step is performed by a method such as CVD.

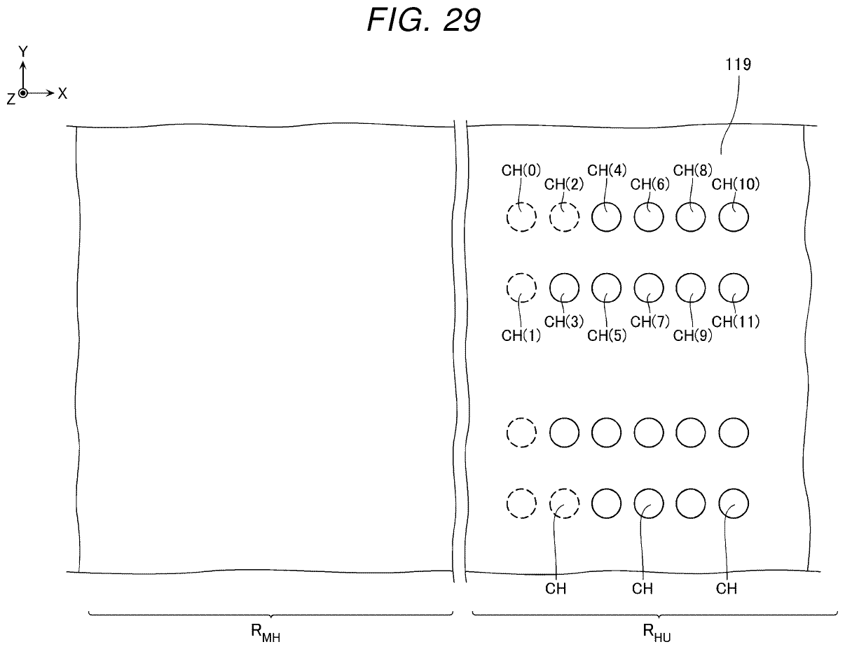

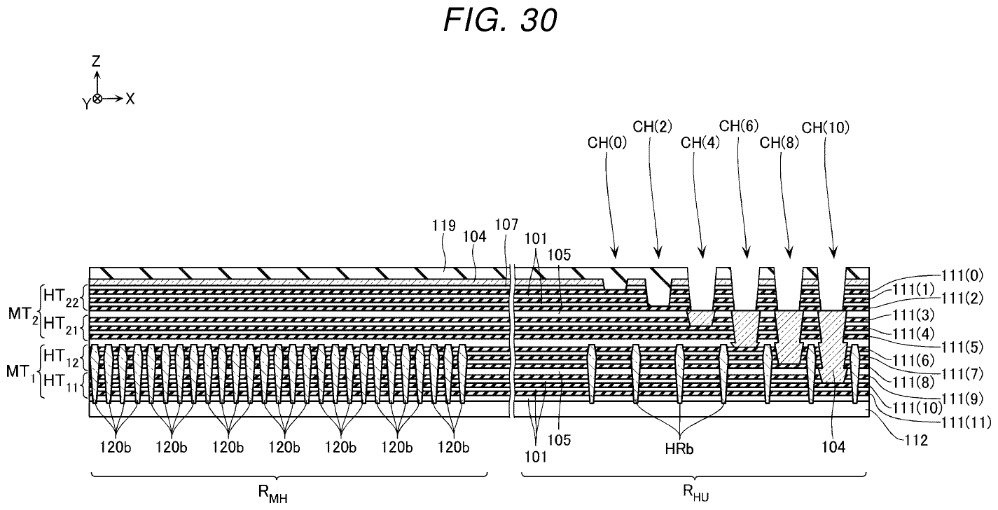

Next, for example, as shown in FIGS. 29 and 30, the contact hole CH is formed at a position corresponding to the contact electrode CC.

In this step, for example, the resist is first formed on the upper surface of the cover layer 104. The resist exposes the upper surface of the cover layer 104 at positions corresponding to the plurality of contact electrodes CC. Next, the cover layer 104 and the insulating layer 107 are removed by a method such as RIE, and the upper surface of the uppermost layer sacrificial layer 111(0) is exposed. In this step, a contact hole CH(0) is formed at a height position corresponding to the divided structure HT22.

Next, the resist is removed to further form a resist. The resist exposes the upper surface of the uppermost layer sacrificial layer 111(0) at positions corresponding to the plurality of contact electrodes CC corresponding to the sacrificial layer 111 in the divided structures HT11, HT12, and HT21. In addition, the resist exposes the upper surface of the uppermost layer sacrificial layer 111(0) at a position corresponding to the contact electrode CC corresponding to the (2a+2)-th (a is an integer of 0 or more) sacrificial layer 111 counted from above in the plurality of contact electrodes CC corresponding to the divided structure HT22. Next, one sacrificial layer 111 and the insulating layer 101 provided on the lower surface of the sacrificial layer 111 are removed by a method such as RIE, and the upper surface of the (2a+2)-th sacrificial layer 111 is exposed. In this step, a contact hole CH(1) is formed at a height position corresponding to the divided structure HT22.

Next, the resist is removed to further form another resist. The resist exposes the upper surface of the sacrificial layer 111 at positions corresponding to the plurality of contact electrodes CC corresponding to the sacrificial layer 111 in the divided structures HT11, HT12, and HT21. In addition, the resist exposes the upper surface of the sacrificial layer 111 at a position corresponding to the contact electrode CC corresponding to the (4a+3)-th and (4a+4)-th (a is an integer of 0 or more) sacrificial layer 111 counted from above, in the plurality of contact electrodes CC corresponding to the divided structure HT22. Next, the two sacrificial layers 111 and the two insulating layers 101 respectively provided on the lower surfaces of the two sacrificial layers 111 are removed by a method such as RIE, and the upper surfaces of the sacrificial layers 111 are exposed. In this step, a contact hole CH(2) is formed at a height position corresponding to the divided structure HT22.

Next, the resist is removed to form another resist 119. The resist 119 exposes the upper surface of the lowermost layer sacrificial layer 111 (2) in the divided structure HT22 at positions corresponding to the plurality of contact electrodes CC corresponding to the sacrificial layer 111 in the divided structures HT11, HT12, and HT21. Next, one sacrificial layer 111 is removed by a method such as RIE, and the upper surface of the cover layer 104 in the divided structure HT21 is exposed. In this step, the plurality of contact holes CH corresponding to the sacrificial layer 111 in the divided structures HT11, HT12, and HT21 are formed at height positions corresponding to the divided structure HT22.

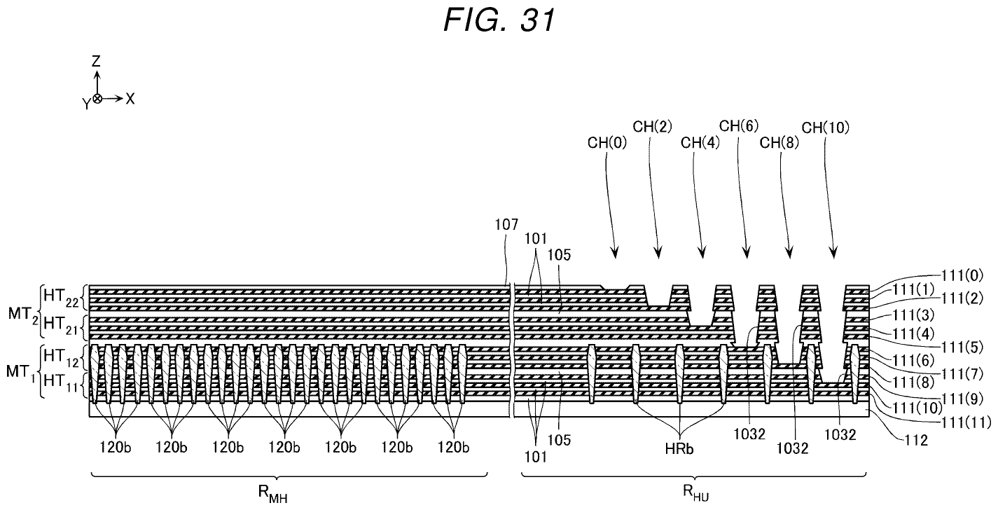

Next, for example, as shown in FIG. 31, the resist 119 and the cover layer 104 are removed. For example, this step is performed by a method such as wet etching.

Next, a film made of silicon nitride (Si3N4) is formed in the contact hole CH, and the block oxide film 1032 is formed by oxidizing the film. For example, this step is performed by a method such as CVD.

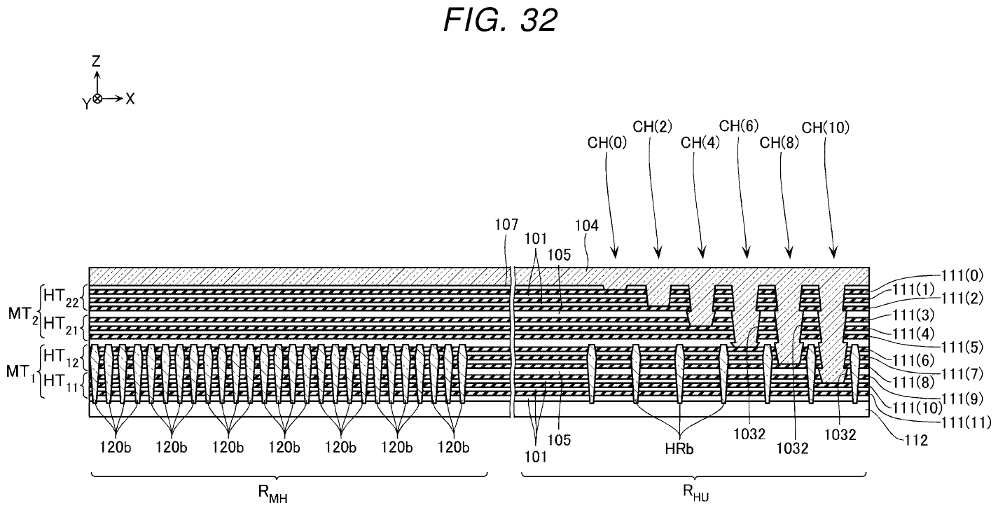

Next, for example, as shown in FIG. 32, the cover layer 104 is formed on the upper surface of the insulating layer 107, and the contact hole CH is embedded. For example, this step is performed by a method such as CVD.

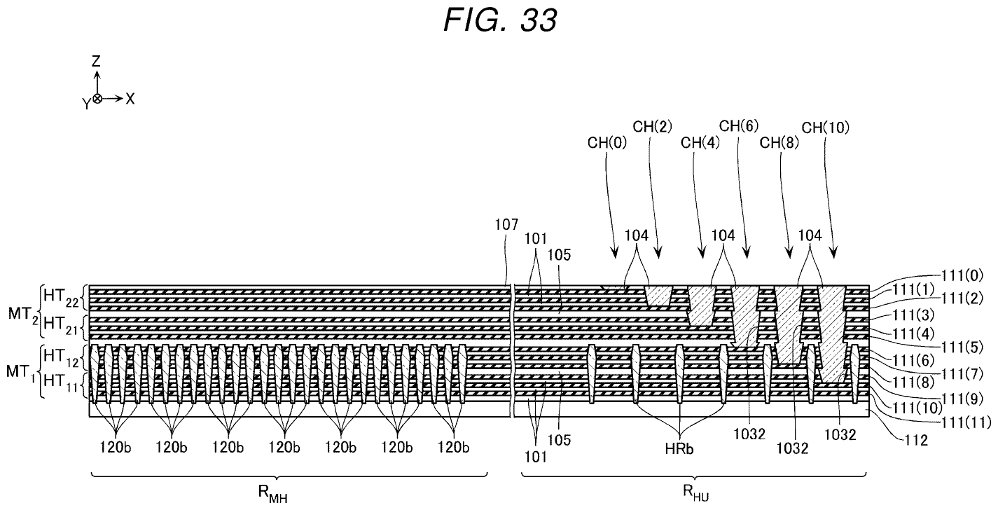

Next, for example, as shown in FIG. 33, a portion of the cover layer 104 is removed to expose the upper surface of the insulating layer 107. For example, this step is performed by a flattening process such as CMP.

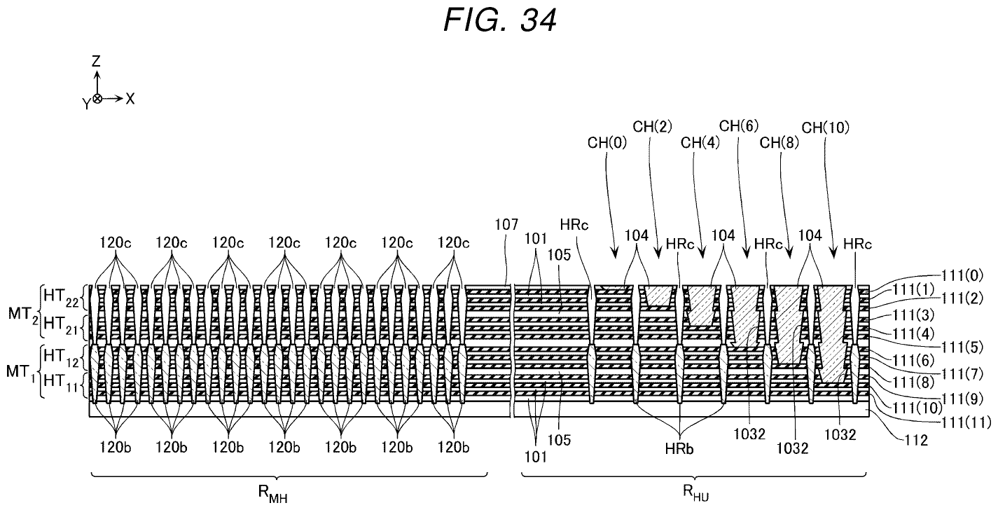

Next, for example, as shown in FIG. 34, a plurality of through-holes 120c are formed at positions corresponding to the plurality of semiconductor columns 120. In addition, a plurality of through-holes HRc are formed at positions corresponding to the plurality of support insulating members HR. The through-holes 120c and HRc each penetrate the plurality of insulating layers 101 and the plurality of sacrificial layers 111 which are provided in the hierarchical structure MT2, and extend in the Z-direction to expose the upper surfaces of sacrificial layers 120b and HRb. For example, this step is performed by a method such as RIE.

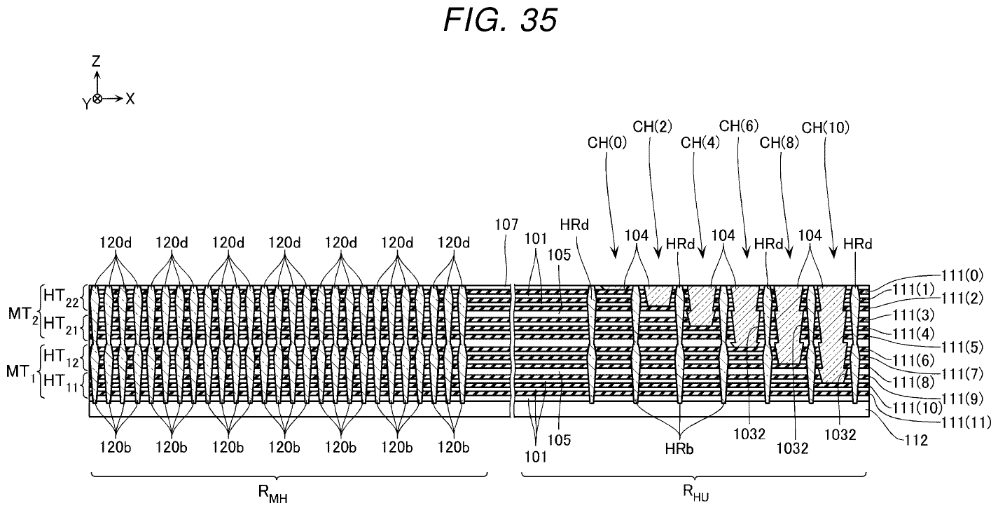

Next, for example, as shown in FIG. 35, the sacrificial layers 120d and HRd made of carbon, for example, are formed in the through-hole 120c and the through-hole HRc. For example, this step is performed by a method such as plasma CVD.

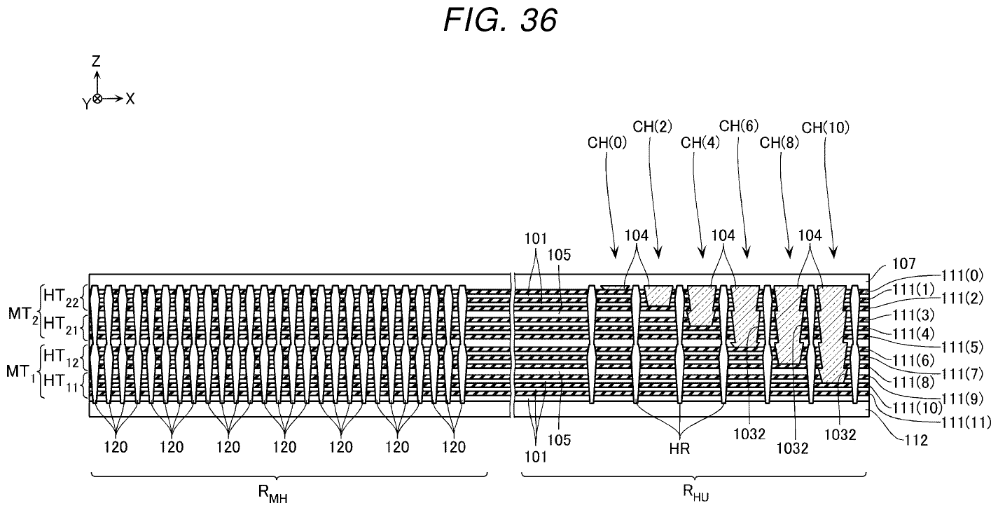

Next, for example, as shown in FIG. 36, the plurality of the semiconductor columns 120 and the plurality of the support insulating members HR are formed. In this step, for example, the sacrificial layers 120b and 120d are removed by a method such as wet etching. Next, the gate insulating film 130 as shown in FIG. 5, the semiconductor column 120, and the insulating layer 125 are formed on inner peripheral surfaces of the through-hole 120a and the through-hole 120c by a method such as CVD. Next, for example, sacrificial layers HRb and HRd are removed by a method such as wet etching. Next, the support insulating member HR is formed in the through-hole HRa and the through-hole HRc by a method such as CVD.

Next, a portion of the insulating layer 107 is further formed on the upper surface of the insulating layer 107. For example, this step is performed by a method such as CVD.

Next, for example, as shown in FIG. 37, the plurality of conductive layers 110 are formed. In this step, for example, a groove penetrating the plurality of insulating layers 101 and the plurality of sacrificial layers 111 which are provided in the hierarchical structure MT1 and the hierarchical structure MT2 is formed at a position corresponding to the inter-block insulating layer ST by a method such as RIE. Next, the plurality of sacrificial layers 111 provided in the hierarchical structure MT1 and the hierarchical structure MT2 are removed by a method such as wet etching via the groove to form a plurality of voids. In this manner, a hollow structure including the plurality of insulating layers 101 arranged in the Z-direction via the void, the plurality of semiconductor columns 120 supporting the plurality of insulating layers 101 in the memory hole region RMH, and the plurality of support insulating members HR supporting the plurality of insulating layers 101 in the hook up region RHU is formed. Next, the plurality of conductive layers 110 provided in the hierarchical structure MT1 and the hierarchical structure MT2 are formed by a method such as CVD.

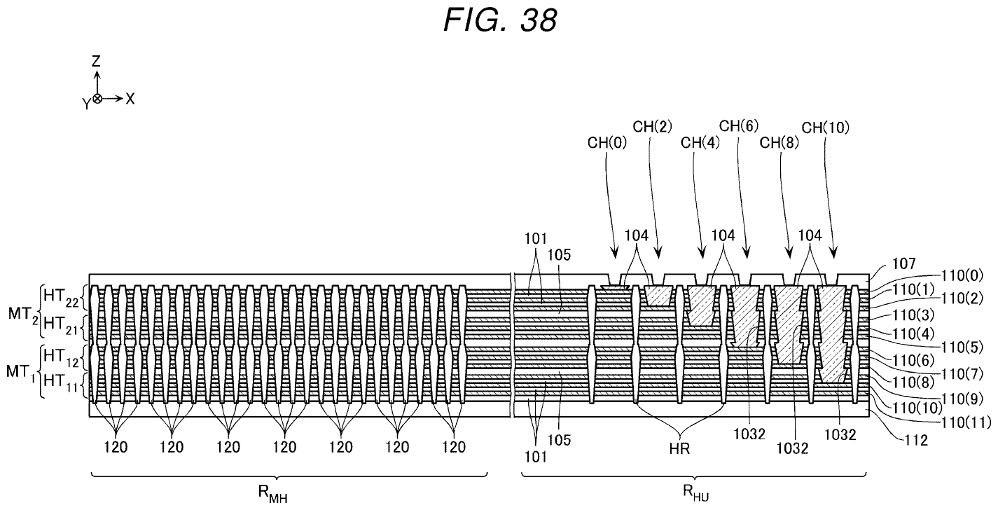

Next, for example, as shown in FIG. 38, a plurality of through-holes are formed in the insulating layer 107 at positions corresponding to the plurality of contact holes CH. The through-holes penetrate a portion of the insulating layer 107, and extend in the Z-direction to expose the upper surface of the cover layer 104. For example, this step is performed by RIE.

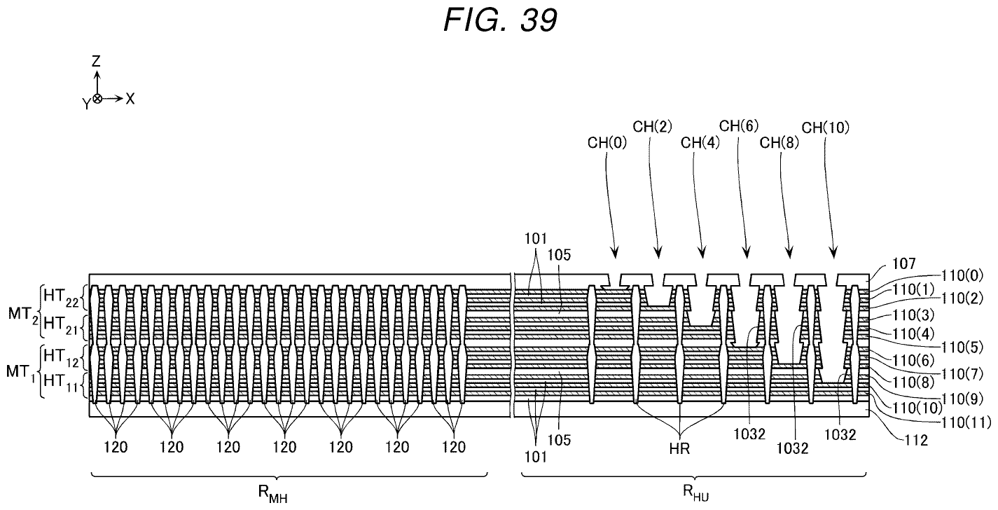

Next, for example, as shown in FIG. 39, the cover layer 104 is removed. For example, this step is performed by a method such as wet etching.

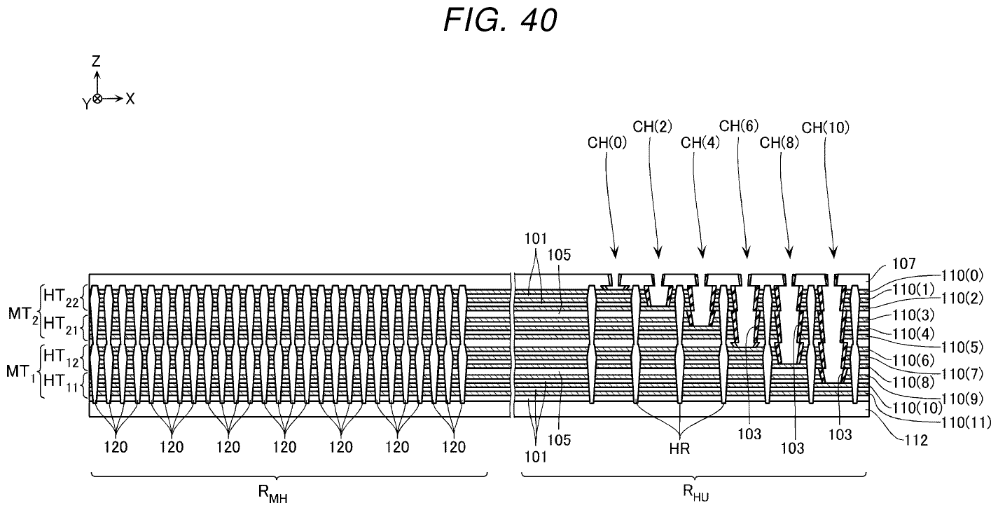

Next, for example, as shown in FIG. 40, the insulating layer 103 is formed in the contact hole CH. In this step, for example, the spacer oxide film 1031 is formed on an inner peripheral surface of the contact hole CH by a method such as CVD. In addition, a portion of the spacer oxide film 1031 and the block oxide film 1032 which is formed on a bottom surface of the contact hole CH is removed to expose the upper surface of the conductive layer 110.

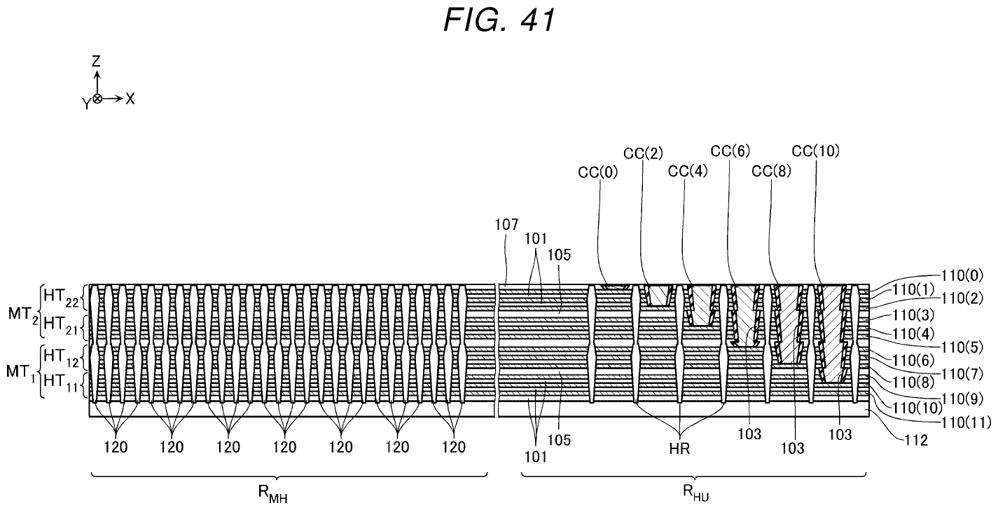

Next, for example, as shown in FIG. 41, the contact electrode CC is formed in the contact hole CH. For example, this step is performed by a method such as CVD.

Thereafter, the semiconductor memory device described with reference to FIGS. 1 to 7 is formed by forming the contact electrodes Ch and Vy, the bit line BL, and the like which are described with reference to FIGS. 6 to 8 by a method such as CVD.

### Comparative Example

### Configuration

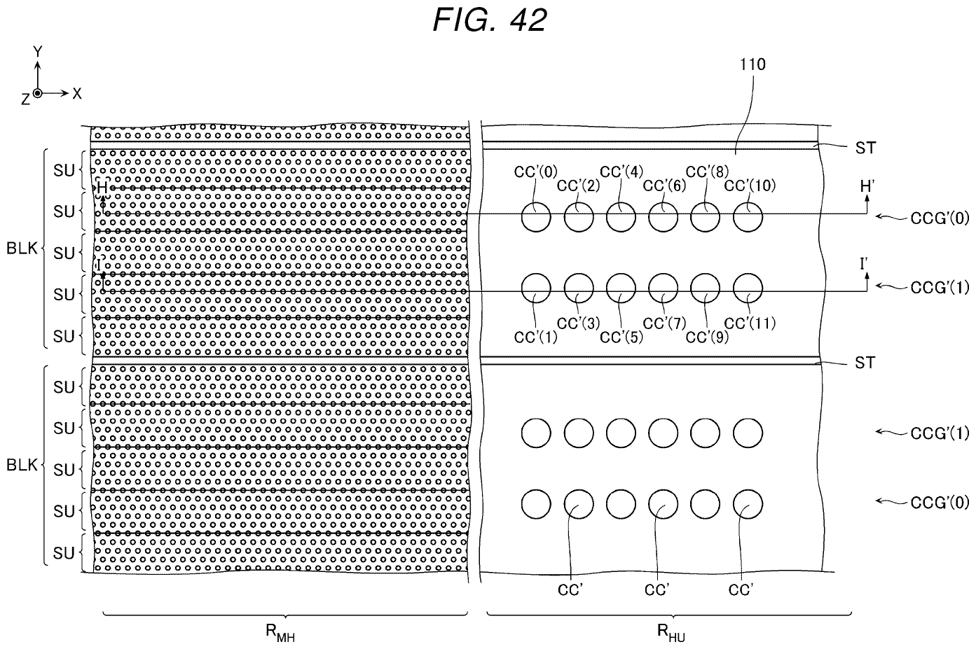

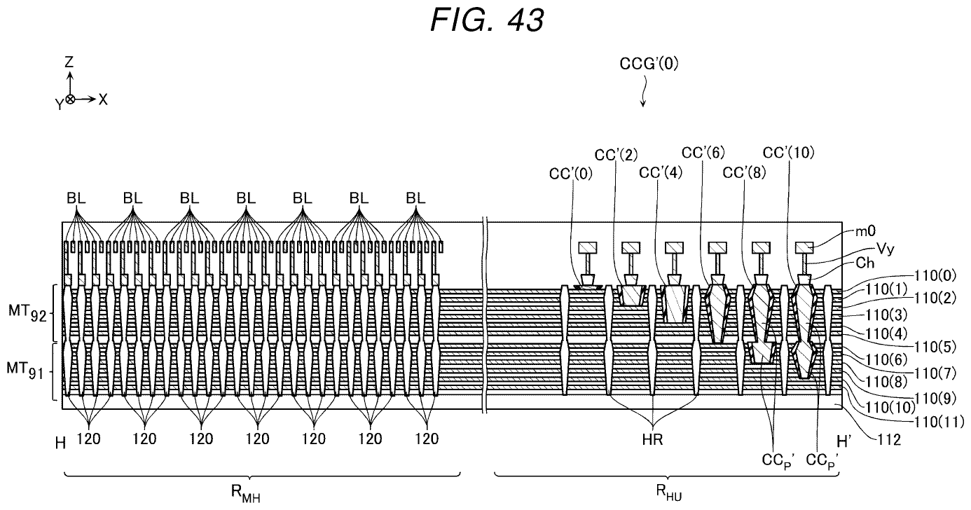

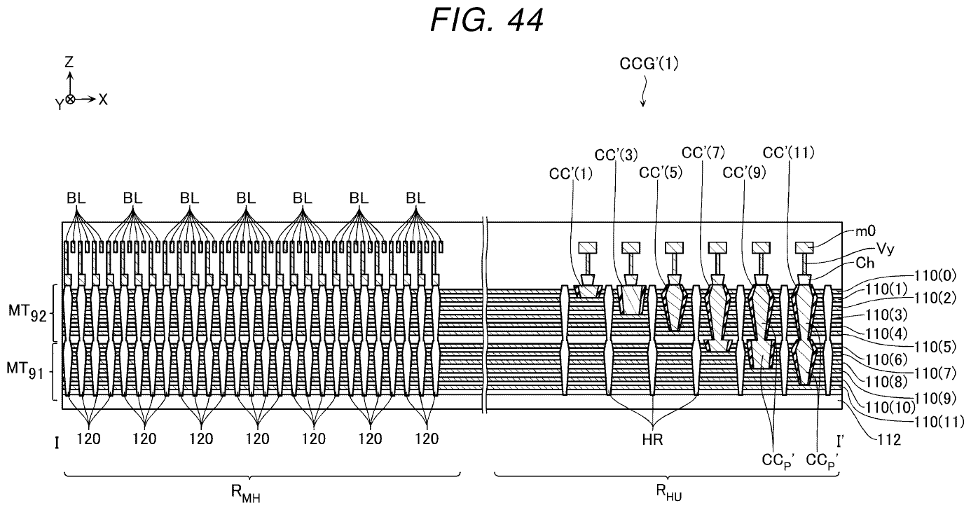

Next, a configuration of a semiconductor memory device according to a comparative example will be described with reference to FIGS. 42 to 44. FIG. 42 is a schematic plan view of the semiconductor memory device according to the comparative example. FIG. 43 is a schematic cross-sectional view when a structure shown in FIG. 42 is taken along line H-H′ and viewed in a direction of an arrow. FIG. 44 is a schematic cross-sectional view when the structure shown in FIG. 42 is taken along line I-I′ and viewed in a direction of an arrow.

The memory block BLK according to the comparative example includes hierarchical structures MT91 and MT92 instead of the hierarchical structures MT1 and MT2. The hierarchical structures MT91 and MT92 do not include the divided structures HT11, HT12, HT21, and HT22, unlike the hierarchical structures MT1 and MT2.

The semiconductor memory device according to the comparative example includes a contact electrode row CCG′ instead of the contact electrode row CCG. In FIG. 42, the two contact electrode rows CCG′ are indicated as CCG′(0) and CCG′(1).

The contact electrode row CCG′(0) includes contact electrodes CC'(0), CC′(2), CC′(4), CC′(6), CC′(8), and CC′(10) in order from the contact electrode row closest to the memory hole region RMH.

The contact electrode row CCG′(1) includes contact electrodes CC′(1), CC′(3), CC′(5), CC′(7), CC′(9), and CC′(11) in order from the contact electrode row closest to the memory hole region RMH.

In the plurality of contact electrodes CC′ according to the comparative example, the contact electrode CC corresponding to the conductive layer 110 in the hierarchical structure MT91 includes two portions CCP′ arranged in the Z-direction which corresponds to the hierarchical structures MT91 and MT92. In the two portions CCP′, a portion CCP′ corresponding to the hierarchical structure MT91 is provided from the lower end of the contact electrode CC′ to a predetermined height position below the lower surface of the lowermost layer conductive layer 110 provided in the hierarchical structure MT92. In the two portions CCP′, a portion CCP′ corresponding to the hierarchical structure MT92 is provided from the predetermined height position to the upper end of the contact electrode CC′. The width of one of the portions CCP′ in the X-direction and the Y-direction (i.e., the diameter when viewed in the Z-direction) increases from the lower end to a predetermined height position, and decreases from the height position to the upper end. The height position where the width of the one of the portions CCP′ in the X-direction and the Y-direction is maximized substantially coincides with the height position where the widths of the portions 123 and HRP in the X-direction and the Y-direction are maximized.

Here, as described above, when a semiconductor memory device according to an embodiment such as the memory die MD is manufactured, the sacrificial layer 111 in the hierarchical structure MT1 is formed in two separate steps including the step described with reference to FIG. 9 and the step described with reference to FIG. 15. In addition, the contact hole CH in the hierarchical structure MT1 is formed in two separate steps. Thereafter, the through-hole HRa is formed. In addition, the sacrificial layer 111 in the hierarchical structure MT2 is formed in two separate steps including the step described with reference to FIG. 23 and the step described with reference to FIG. 28. In addition, the contact hole CH in the hierarchical structure MT2 is formed in two separate steps. Thereafter, the through-hole HRc is formed.

On the other hand, when the semiconductor memory device according to the comparative example is manufactured, in the step corresponding to FIG. 9, all of the sacrificial layers 111 in the hierarchical structure MT91 are formed, and the step corresponding to FIG. 15 is not performed. In addition, after the step corresponding to FIG. 9 is performed, the contact hole CH corresponding to all of the sacrificial layers 111 in the hierarchical structure MT91 is formed, and the through-hole HRa is formed.

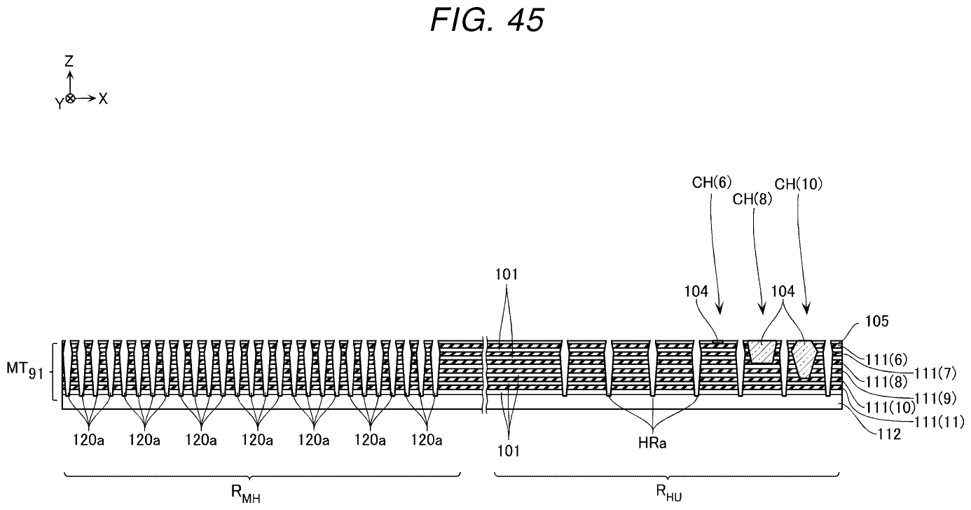

FIG. 45 is a schematic cross-sectional view illustrating a manufacturing method of the semiconductor memory device according to the comparative example, and shows a state after the step corresponding to FIG. 21 is performed. As shown in the drawing, in a manufacturing step of the semiconductor memory device according to the comparative example, in some of the contact holes CH (in the example shown in the drawing, the contact hole CH(10)), a height position where the width in the X-direction and the Y-direction is maximized substantially coincides with a height position where the width of the through-hole HRa in the X-direction and in the Y-direction is maximized. The reason is as follows. Both the contact hole CH corresponding to the hierarchical structure MT91 and the through-hole HRa corresponding to the hierarchical structure MT91 are formed in a state where all of the sacrificial layers 111 corresponding to the hierarchical structure MT91 are formed.

Similarly, when the semiconductor memory device according to the comparative example is manufactured, all of the sacrificial layers 111 in the hierarchical structure MT92 are formed in the step corresponding to FIG. 23, and the step corresponding to FIG. 28 is not performed. In addition, after the step corresponding to FIG. 23 is performed, the contact hole CH corresponding to all of the sacrificial layers 111 in the hierarchical structure MT92 is formed, and the through-hole HRc is formed.

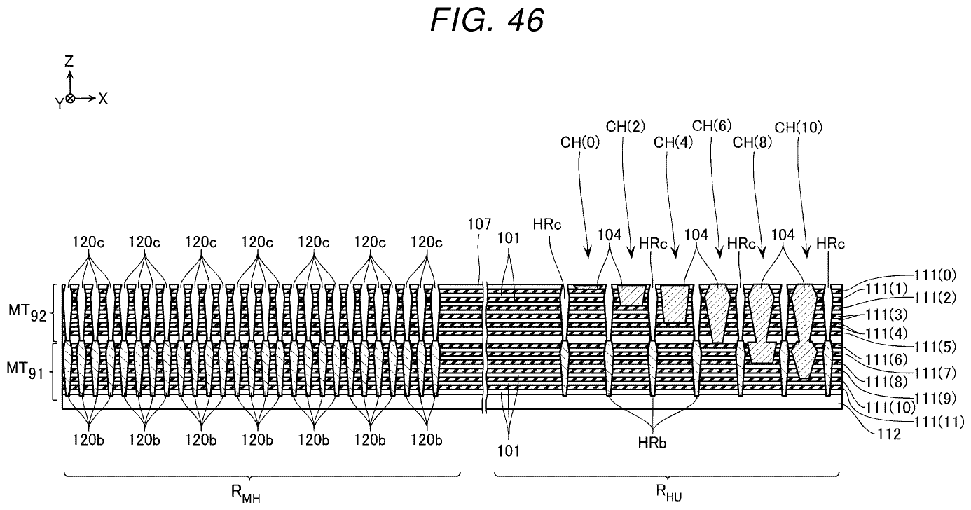

FIG. 46 is a schematic cross-sectional view illustrating the manufacturing method of the semiconductor memory device according to the comparative example, and shows a state after the step corresponding to FIG. 34 is performed. As shown in the drawing, in the manufacturing step of the semiconductor memory device according to the comparative example, in some of the contact holes CH (in the example shown in the drawing, the contact holes CH(6), CH(8), and CH(10)), a height position where the width in the X-direction and the Y-direction is maximized substantially coincides with a height position where the width in the X-direction and the Y-direction of the through-hole HRc is maximized. The reason is as follows. Both the contact hole CH corresponding to the hierarchical structure MT92 and the through-hole HRc corresponding to the hierarchical structure MT92 are formed in a state where all of the sacrificial layers 111 corresponding to the hierarchical structure MT92 are formed.

### Advantageous Effects

As a semiconductor memory device is highly integrated, an aspect ratio (i.e., a ratio of the length in the Z-direction to the width in the X-direction and the Y-direction) of the semiconductor column 120, the support insulating member HR, and the contact electrode CC continuously increases. When a through-hole having a high aspect ratio is formed by a method such as RIE, the width of the through-hole in the X-direction and the Y-direction (i.e., the diameter when viewed in the Z-direction) may increase from the lower end to the predetermined height position, and may decrease from the height position to the upper end.

Here, in order to highly integrate the semiconductor memory device, it is desirable that a distance between the contact electrodes CC is short. In addition, in order to preferably support the plurality of insulating layers 101 in the step described with reference to FIG. 37, it is desirable to dispose the support insulating members HR at a predetermined interval. Meanwhile, as described with reference to FIGS. 45 and 46, when the semiconductor memory device according to the comparative example is manufactured, in some of the contact holes CH, the height position where the width in the X-direction and the Y-direction is maximized substantially coincides with the height position where the widths in the X-direction and the Y-direction of the through-holes HRa and HRc are maximized. Therefore, when the contact hole CH and the through-holes HRa and HRc are closer to each other to have a predetermined or longer distance, there is a possibility that the cover layer 104 in the contact hole CH is exposed on the inner peripheral surfaces of the through-holes HRa and HRc. In this state, when the sacrificial layers HRb and HRd in the through-holes HRa and HRc are removed in the step corresponding to FIG. 35, the cover layer 104 in the contact hole CH is also removed. In addition, in this state, when the support insulating member HR is formed in the through-holes HRa and HRc, an insulating layer made of silicon oxide or the like is formed on the bottom surface, an upper surface, and an inner peripheral surface of the contact hole CH, and consequently, the contact electrode CC cannot be formed.

Therefore, when the semiconductor memory device such as the memory die MD described above is manufactured, the sacrificial layer 111 in the hierarchical structure MT1 is formed in two separate steps including the step described with reference to FIG. 9 and the step described with reference to FIG. 15. In addition, the contact hole CH in the hierarchical structure MT1 is formed in two separate steps. Thereafter, the through-hole HRa is formed. In addition, the sacrificial layer 111 in the hierarchical structure MT2 is formed in two separate steps including the step described with reference to FIG. 23 and the step described with reference to FIG. 28. In addition, the contact hole CH in the hierarchical structure MT2 is formed in two separate steps. Thereafter, the through-hole HRc is formed.

In this manner, in the semiconductor memory device, the height position in the Z-direction of the portion having the largest width or diameter in the contact hole CH and the height position in the Z-direction of the portion having the largest width or diameter in the through-holes HRa and HRc are different from each other. Therefore, the cover layer 104 in the contact hole CH is less likely to be exposed on the inner peripheral surfaces of the through-holes HRa and HRc.

In addition, since the contact hole CH is formed in two separate steps in the hierarchical structure MT1 and the hierarchical structure MT2, it is possible to reduce the aspect ratio of the portion of the contact hole CH which is formed in one step corresponding to the portion CCP. In this manner, it is possible to prevent a shape of the contact hole CH from becoming a shape in which the width in the X-direction and the Y-direction (i.e., the diameter when viewed in the Z-direction) increases from the lower end to the predetermined height position, and decreases from the height position to the upper end. Therefore, it is possible to adopt a configuration in which the distance from the through-holes HRa and HRc is easily secured.

In addition, when the semiconductor memory device is manufactured, the contact hole CH in the hierarchical structure MT1 is formed in two separate steps, and the contact hole CH in the hierarchical structure MT2 is formed in two separate steps. Therefore, the aspect ratio of the contact hole CH formed each time is reduced, and a selection ratio during etching of the contact hole CH formed each time is reduced. In this manner, even when the contact hole CH is formed multiple separate steps (e.g., four steps in the above-described example), a deviation of the contact hole CH (or thethrough-hole) in the Z-axis direction in each step can be prevented. In addition, since the contact hole CH is formed in multiple separate steps (e.g., four steps), a thickness of a resist film applied when the contact hole CH is formed in one step can be relatively increased.

### Other Embodiments

The configuration and the manufacturing method of the semiconductor memory device described above are merely examples, and they can be appropriately adjusted.

For example, the memory block BLK includes the plurality of (two in the example shown in the drawing) hierarchical structures MT1 and MT2 arranged in the Z-direction. Meanwhile, the memory block BLK may include a three or more hierarchical structures. Furthermore, the semiconductor column 120 and the support insulating member HR may include three or more configurations corresponding to the portions 123 and HRP corresponding to the three or more hierarchical structures.

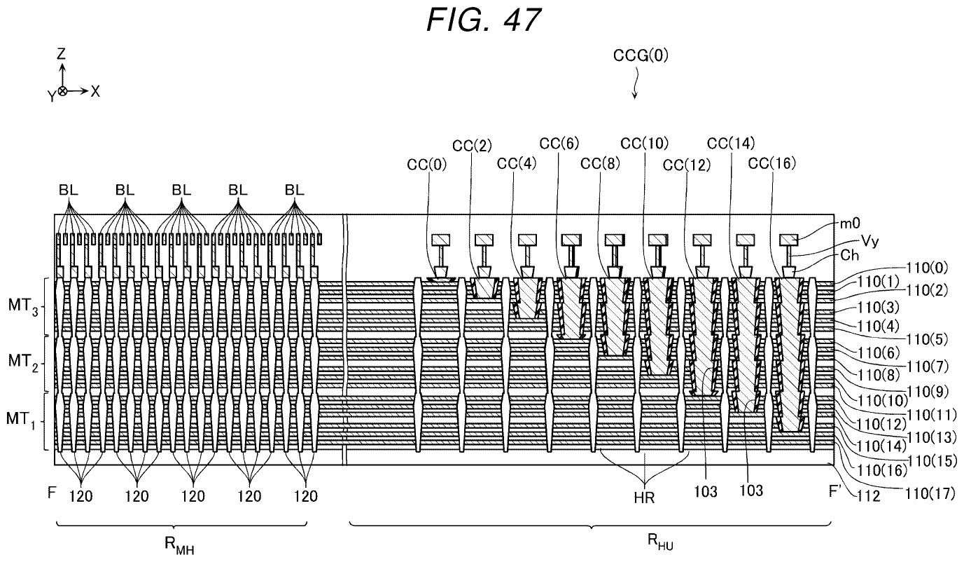

FIG. 47 is a schematic cross-sectional view of a semiconductor memory device according to another embodiment.

As shown in FIG. 47, the semiconductor memory device according to another embodiment includes three hierarchical structures MT1, MT2, and MT3 arranged in the Z-direction. In addition, each of the three hierarchical structures MT1, MT2, and MT3 includes two divided structures arranged in the Z-direction. The other structures are the same as the ones described with reference to the previous drawings, and thus, description thereof will be omitted.

For example, each of the hierarchical structures in the memory block BLK may include three or more divided structures arranged in the Z-direction. Furthermore, the contact electrode CC may include three or more configurations corresponding to the portion CCP corresponding to the three or more divided structures.

In addition, for example, one end of the semiconductor column 120 in the Z-direction is connected to the semiconductor layer 112. Meanwhile, one end of the semiconductor column 120 in the Z-direction may be connected to the semiconductor substrate 100. In addition, the configuration in the embodiment may be formed upside down.

### Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a plurality of conductive layers arranged in a first direction and extending along a second direction crossing the first direction;
a semiconductor column penetrating the conductive layers;
a charge storage film between the semiconductor column and the conductive layers;
a conductive line extending above the conductive layers in the first direction and electrically connected to the semiconductor column; and
a contact electrode penetrating one or more of the conductive layers to contact an upper surface of one of the conductive layers other than said one or more of the conductive layers, wherein
the semiconductor column includes a plurality of first portions arranged in the first direction, wherein a width in the second direction of an upper part of each of the first portions is greater than a width in the second direction of a lower part of said each of the first portions,
the contact electrode includes a plurality of second portions arranged in the first direction, wherein a width in the second direction of an upper part of each of the second portions is greater than a width in the second direction of a lower part of said each of the second portions, and
a total number of the second portions is greater than a total number of the first portions.

2. The semiconductor memory device according to claim 1, wherein
an outer peripheral surface of the contact electrode is surrounded by and insulated from said one or more of the conductive layers.

3. The semiconductor memory device according to claim 1, wherein
the second portions are between a first level that corresponds to a lower end of a lowermost one of the first portions and a second level that corresponds to an upper end of a uppermost one of the first portions in the first direction.

4. The semiconductor memory device according to claim 1, wherein
the second portions are between a third level that corresponds to a lower end of one of the first portions and a fourth level that corresponds to an upper end of said one of the first portions in the first direction.

5. The semiconductor memory device according to claim 1, wherein
a part of each of the first portions at which the width is greatest is shifted in the first direction from a part of each of the second portions at which the width is greatest.

6. The semiconductor memory device according to claim 1, wherein
a width of one of the first portions in the second direction increases from a lower end of said one of the first portions to a particular part thereof, and decreases from the particular part to an upper end of said one of the first portions.

7. The semiconductor memory device according to claim 6, wherein
a width of each of the second portions in the second direction increases from a lower end to an upper end thereof.

8. The semiconductor memory device according to claim 1, further comprising:
a support insulating member penetrating the conductive layers and including a plurality of third portions arranged in the first direction, wherein
a width in the second direction of an upper part of each of the third portions is greater than a width in the second direction of a lower part of said each of the third portions, and
the total number of the second portions is greater than a total number of the third portions.

9. The semiconductor memory device according to claim 8, wherein
the total number of the third portions is equal to the total number of the first portions.

10. The semiconductor memory device according to claim 8, wherein
the second portions are between a fifth level that corresponds to a lower end of a lowermost one of the third portions and a sixth level that corresponds to an upper end of a uppermost one of the third portions in the first direction.

11. The semiconductor memory device according to claim 8, wherein
the second portions are between a seventh level that corresponds to a lower end of one of the third portions and a eights level that corresponds to an upper end of said one of the third portions in the first direction.

12. The semiconductor memory device according to claim 8, wherein
a part of each of the third portions at which the width is greatest is shifted in the first direction from a part of each of the second portions at which the width is greatest.

13. The semiconductor memory device according to claim 12, wherein
a part of one of the first portions at which the width is greatest and a part of one of the third portions at which the width is greatest are substantially at a same level in the first direction.

14. The semiconductor memory device according to claim 8, wherein
a width of one of the third portions in the second direction increases from a lower end of said one of the third portions to a particular part thereof, and decreases from the particular part to an upper end of said one of the third portions.

15. The semiconductor memory device according to claim 14, wherein
a width of each of the second portions in the second direction increases from a lower end to an upper end thereof.

16. The semiconductor memory device according to claim 15, wherein
a width of one of the first portions in the second direction increases from a lower end of said one of the first portions to a particular part thereof, and then decreases from the particular part to an upper end of said one of the first portions.

17. A semiconductor memory device comprising:
a plurality of conductive layers arranged along a first direction and extending along a second direction crossing the first direction;
a semiconductor column penetrating the conductive layers;
a charge storage film between the semiconductor column and the conductive layers;
a conductive line extending above the conductive layers in the first direction and electrically connected to the semiconductor column;
a contact electrode penetrating one or more of the conductive layers to contact an upper surface of one of the conductive layers other than said one or more of the conductive layers; and
a support insulating member penetrating the conductive layers, wherein
the semiconductor column includes a plurality of first portions arranged in the first direction, wherein a width in the second direction of an upper part of each of the first portions is greater than a width in the second direction of a lower part of said each of the first portions,
the contact electrode includes a plurality of second portions arranged in the first direction, wherein a width in the second direction of an upper part of each of the second portions is greater than a width in the second direction of a lower part of said each of the second portions,
the support insulating member includes a plurality of third portions arranged in the first direction, wherein a width in the second direction of an upper part of each of the third portions is greater than a width in the second direction of a lower part of said each of the third portions, and
a total number of the second portions is greater than a total number of the third portions.

18. The semiconductor memory device according to claim 17, wherein
an outer peripheral surface of the contact electrode is surrounded by and insulated from said one or more of the conductive layers.

19. The semiconductor memory device according to claim 17, wherein
a part of each of the third portions at which the width is greatest is shifted in the first direction from a part of each of the second portions at which the width is greatest.

20. The semiconductor memory device according to claim 17, wherein
a width of one of the third portions in the second direction increases from a lower end of said one of the third portions to a particular part thereof, and decreases from the particular part to an upper end of said one of the third portions, and
a width of each of the second portions in the second direction increases from a lower end to an upper end thereof.
